(19) United States
(12) Patent Application Publication
(10) Pub. No.: US 2015/0102358 A1
(43) Pub. Date: Apr. 16, 2015

(54) NITRIDE SEMICONDUCTOR MULTILAYER STRUCTURE, SEMICONDUCTOR LIGHT-EMITTING DEVICE, AND METHOD FOR MANUFACTURING NITRIDE SEMICONDUCTOR MULTILAYER STRUCTURE

(71) Applicant: Panasonic Intellectual Property Management Co., Ltd., Osaka (JP)

(72) Inventor: SONGBAEK CHOE, Osaka (JP)

(21) Appl. No.: 14/509,048

(22) Filed: Oct. 8, 2014

(30) Foreign Application Priority Data
Oct. 11, 2013 (JP) 2013-213903

(51) Int. Cl. H01L 33/00; H01L 33/32; H01L 33/16; H01L 33/12

(52) U.S. Cl. CPC H01L 33/0025; H01L 33/0075; H01L 33/0066; H01L 33/12; H01L 33/32; H01L 33/16
USPC 257/76; 438/47

(57) ABSTRACT

A nitride semiconductor multilayer structure includes a sapphire substrate having an m-plane principal surface with an off-angle φ, and a mask layer including first and second side surface portions that sandwich each exposed region. In a cross section parallel to the m- and c-axes, points at which the first and second side surface portions meet the principal surface are respectively points A and B, a point at which the first side surface portion intersects a line passing through point B and forming an angle of 58°−φ with the principal surface is C, a distance between a line passing through point C and perpendicular to the principal surface and a line passing through point B and perpendicular to the principal surface is W, and a height of the first side surface portion is H. Then H≧W·tan(58°−φ)).

### CROSS REFERENCES TO RELATED APPLICATIONS

This application claims priority to Japanese Patent Application No. 2013-213903, filed on Oct. 11, 2013, the contents of which are hereby incorporated by reference.

### BACKGROUND

1. Technical Field

This disclosure relates to a nitride semiconductor multilayer structure and a manufacturing method therefor.

2. Description of the Related Art

In general, making high-grade semiconductor layers from group III nitride semiconductors is not as easy as making high-grade semiconductor layers from silicon semiconductors. There have been various proposals of methods for forming high-grade semiconductor layers.

U.S. Pat. No. 6,809,351 discloses a method with which a group III nitride semiconductor layer with fewer defects can be made by forming a stripe mask having a high aspect ratio on a substrate so as to terminate propagation of dislocations.

U.S. Pat. No. 8,330,144 discloses a method for suppressing defects occurring in a nitride semiconductor layer. According to this method, a dielectric mask is formed on a substrate having a semi-polar surface tilted from the c-plane as a principal surface and a nitride semiconductor layer is grown on the substrate.

Philippe Vennegues et al., Study of the epitaxial relationships between III-nitrides and M-plane sapphire, Journal of Applied Physics, vol. 108, page 113521 (2010) discloses epitaxially growing a nitride semiconductor layer having an non-polar surface or a semi-polar surface on an m-plane sapphire substrate. The nitride semiconductor layer grown has one principal surface selected from the group consisting of a (10-10) surface, a (11-22) surface, and a (10-1-3) surface depending on the conditions of the epitaxial growth.

### SUMMARY

Non-limiting exemplary embodiments of this disclosure provide nitride semiconductor multilayer structures having low dislocation densities and manufacturing methods therefor.

A nitride semiconductor multilayer structure according to an embodiment of the disclosure includes a sapphire substrate having a principal surface which is an m-plane having an off-angle φ of 0° or more and 10° or less with respect to a c-axis; a mask layer having a pattern that forms a plurality of exposed regions on the principal surface of the sapphire substrate, the mask layer including a first side surface portion and a second side surface portion sandwiching each of the exposed regions in a direction parallel to the c-axis of the sapphire substrate; a buffer layer disposed on the plurality of exposed regions of the principal surface and the mask layer, the buffer layer including a nitride semiconductor; and a nitride semiconductor layer disposed on the buffer layer. In a cross section parallel to an m-axis and the c-axis of the sapphire substrate, a point at which the first side surface portion of the mask layer meets the principal surface of the sapphire substrate is defined as point A and a point at which the second side surface portion of the mask layer meets the principal surface of the sapphire substrate is defined as point B, a point at which the first side surface portion intersects a straight line passing through point B and forming an angle 58°−φ with the principal surface is defined as point C, a distance between a straight line passing through point C and perpendicular to the principal surface and a straight line passing through point B and perpendicular to the principal surface is defined as W, and a height of the first side surface portion is defined as H. In the cross section, H≧W·tan(58°−φ).

It should be noted that general or specific embodiments may be implemented as an element, a device, a method, or any elective combination thereof.

According to an embodiment of the disclosure, a nitride semiconductor multilayer structure having a low dislocation density can be obtained.

Additional benefits and advantages of the disclosed embodiments will be apparent from the specification and Figures. The benefits and/or advantages may be individually provided by the various embodiments and features of the specification and Figures, and need not all be provided in order to obtain one or more of the same.

### BRIEF DESCRIPTION OF THE DRAWINGS

FIG. 1 is a cross-sectional view of a nitride semiconductor multilayer structure according to a first embodiment.

FIG. 2A is a plan view of a mask layer of the nitride semiconductor multilayer structure according to the first embodiment.

FIG. 2B is a cross-sectional view of the nitride semiconductor multilayer structure according to the first embodiment.

FIG. 3 is a plan view of another embodiment example of the mask layer.

FIG. 4 is a cross-sectional view of a nitride semiconductor multilayer structure in the process of forming a nitride semiconductor layer according to the first embodiment.

FIG. 5 is another cross-sectional view of the nitride semiconductor multilayer structure in the process of forming a nitride semiconductor layer according to the first embodiment.

FIG. 6 is a cross-sectional view of a light-emitting device according to a second embodiment.

FIG. 7 is a cross-sectional view of a light-emitting apparatus according to a third embodiment.

FIG. 8A is a plan view of one step of a method for manufacturing a nitride semiconductor multilayer structure according to Example.

FIG. 8B is a cross-sectional view taken along line VIIIB-VIIIB in FIG. 8A.

FIG. 9A is a plan view of another step of the method for manufacturing a nitride semiconductor multilayer structure according to Example.

FIG. 9B is a cross-sectional view taken along line IXB-IXB in FIG. 9A.

FIG. 10A is a plan view of another step of the method for manufacturing a nitride semiconductor multilayer structure according to Example.

FIG. 10B is a cross-sectional view taken along line XB-XB in FIG. 10A.

FIG. 11A is a plan view of another step of the method for manufacturing a nitride semiconductor multilayer structure according to Example.

FIG. 11B is a cross-sectional view taken along line XIB-XIB in FIG. 11A.

FIG. 12 is a cross-sectional photograph of a substrate equipped with a mask layer according to Example 1.

FIG. 13 is an X-ray diffraction profile of a nitride semiconductor multilayer structure according to Comparative Example 1.

FIG. 14A is a cross-sectional scanning electron microscope image (SEM image) of the nitride semiconductor multilayer structure according to Comparative Example 1.

FIG. 14B is a cross-sectional SEM image of a nitride semiconductor multilayer structure according to Example 1.

FIG. 14C is a cross-sectional SEM image of a nitride semiconductor multilayer structure according to Reference Example A.

FIG. 15 is an emission spectrum diagram of nitride semiconductor layers 300 at a low temperature of 10 K in Comparative Example 1 and Example 1.

FIG. 16A is a cross-sectional transmission electron microscope image (TEM image) of the nitride semiconductor multilayer structure according to Reference Example A.

FIG. 16B is an enlarged view of a region surrounded by a broken line in FIG. 16A.

FIG. 16C is an enlarged view of a region surrounded by a broken line in FIG. 16B.

FIG. 17A is an image of a surface morphology of the nitride semiconductor multilayer structure of Reference Example A taken at a particular point within a sample plane.

FIG. 17B is an image of a surface morphology of the nitride semiconductor multilayer structure of Reference Example A taken at another point within the sample plane.

FIG. 17C is an image of a surface morphology of the nitride semiconductor multilayer structure of Reference Example A taken at yet another point within the sample plane.

FIG. 18A is an image of a surface morphology of the nitride semiconductor multilayer structure of Example 1.

FIG. 18B is an enlarged view of the surface morphology of the nitride semiconductor multilayer structure according to Example 1.

FIG. 19A is a cross-sectional TEM image of the nitride semiconductor multilayer structure of Example 1.

FIG. 19B is an enlarged view of a central part of FIG. 19A.

FIG. 19C is an enlarged view of a region surrounded by a broken line in FIG. 19B.

FIG. 20A is an image of a surface morphology of the nitride semiconductor multilayer structure of Comparative Example 1.

FIG. 20B is an image of a surface morphology of the nitride semiconductor multilayer structure of Reference Example 1.

FIG. 20C is an image of a surface morphology of a nitride semiconductor multilayer structure of Reference Example 2.

### DETAILED DESCRIPTION OF THE EMBODIMENTS

### Studies that have LED to this Disclosure

The method for suppressing defects disclosed in U.S. Pat. No. 8,330,144 has been closely studied. According to the method, a nitride semiconductor layer is used as an underlayer. According to the method, a nitride semiconductor layer having a semi-polar surface is formed on a sapphire substrate, a dielectric layer is formed on the nitride semiconductor layer, and another nitride semiconductor layer having a semi-polar nitride semiconductor layer is formed on the dielectric layer. In other words, a crystal growing step for forming a nitride semiconductor layer is performed twice. This increases the production cost and requires a longer production time.

To overcome these challenges, a novel nitride semiconductor multilayer structure has been conceived. A nitride semiconductor multilayer structure according to one embodiment of the disclosure uses a structure and a method with which a dielectric mask pattern is directly formed on a sapphire substrate and a nitride semiconductor layer having a semi-polar surface is grown over the mask pattern. Since crystal growth can be conducted after subjecting the sapphire substrate to dielectric mask patterning, the crystal growth step needs to be performed just once and the production cost can be significantly reduced. The defects propagating in diagonal directions at the interface between the sapphire substrate and the nitride semiconductor layer can be blocked by the dielectric mask side surfaces. Thus, the defect density at the surface of the semi-polar nitride semiconductor layer can be decreased and the crystal quality can be improved. The specific details of a nitride semiconductor multilayer structure according to an embodiment are as follows.

### Summary of Embodiments

A nitride semiconductor multilayer structure according to an embodiment of this disclosure includes a sapphire substrate having a principal surface which is an m-plane having an off-angle φ of 0° or more and 10° or less with respect to a c-axis; a mask layer having a pattern that forms a plurality of exposed regions on the principal surface of the sapphire substrate, the mask layer including a first side surface portion and a second side surface portion sandwiching each of the exposed regions in a direction parallel to the c-axis of the sapphire substrate; a buffer layer disposed on the plurality of exposed regions of the principal surface and the mask layer, the buffer layer including a nitride semiconductor; and a nitride semiconductor layer disposed on the buffer layer. In a cross section parallel to an m-axis and the c-axis of the sapphire substrate, a point at which the first side surface portion of the mask layer meets the principal surface of the sapphire substrate is defined as point A, a point at which the second side surface portion of the mask layer meets the principal surface of the sapphire substrate is defined as point B, a point at which the first side surface portion intersects a straight line passing through point B and forming an angle 58°−φ with the principal surface is defined as point C, a distance between a straight line passing through point C and perpendicular to the principal surface and a straight line passing through point B and perpendicular to the principal surface is defined as W, a height of the first side surface portion is defined as H, and H≧W·tan(58°−φ).

When, in the cross section parallel to the m-axis and the c-axis of the sapphire substrate, a region defined by the principal surface, the first side surface portion, and a straight line connecting point B and point C is defined as a first region, a region defined by the second side surface portion, the straight line connecting point B and point C, and a straight line passing through point C and parallel to the principal surface is defined as a second region, and a region above the straight line passing through point C and parallel to the principal surface is defined as a third region, the nitride semiconductor layer may have a higher dislocation density in the first region than in the second region.

For example, the nitride semiconductor layer may have the same dislocation density in the second region and the third region.

For example, the nitride semiconductor layer may have a dislocation density of 10⁸ cm⁻² or less in the third region.

For example, the nitride semiconductor layer may have a dislocation density of 10ⁿ cm⁻² or more in the first region.

For example, the nitride semiconductor layer may have a dislocation density of 10⁸ cm⁻² or less in the second region.

For example, a crystal structure of the buffer layer on the plurality of exposed regions of the principal surface may be different from a crystal structure of the buffer layer on the mask layer.

For example, the buffer layer on the plurality of exposed regions of the principal surface may have the same plane orientation as that of the nitride semiconductor layer.

For example, the buffer layer may include an aluminum-containing nitride semiconductor.

For example, the mask layer may have a striped structure extending in an a-axis direction of the sapphire substrate and including a plurality of stripes that include a pair of stripes adjacent to each other. The first side surface portion and the second side surface portion may be side surfaces of the pair of stripes, the side surfaces opposing each other.

For example, the mask layer may include a plurality of independent openings and the plurality of exposed regions of the principal surface may be located at bottoms of the plurality of openings.

For example, each of the plurality of openings may have a round shape.

For example, each of the plurality of openings may have a stripe shape.

An electronic device according to an embodiment of the disclosure includes the nitride semiconductor multilayer structure described above.

A nitride semiconductor bulk substrate according to an embodiment of the disclosure includes the nitride semiconductor multilayer structure described above.

A light-emitting device according to an embodiment of the disclosure includes the nitride semiconductor multilayer structure described above; an additional nitride semiconductor multilayer structure disposed on the nitride semiconductor multilayer structure, the additional nitride semiconductor multilayer structure including an n-type nitride semiconductor layer, a p-type nitride semiconductor layer, and an active layer sandwiched between the n-type nitride semiconductor layer and the p-type nitride semiconductor layer; an n-side electrode in contact with and electrically connected to the n-type nitride semiconductor layer; and a p-side electrode in contact with and electrically connected to the p-type nitride semiconductor layer.

A method for manufacturing a nitride semiconductor multilayer structure according to an embodiment of this disclosure includes preparing a sapphire substrate having a principal surface which is an m-plane having an off-angle φ of 0° or more and 10° or less with respect to a c-axis; forming a mask layer on the principal surface of the sapphire substrate, the mask layer having a pattern that forms a plurality of exposed regions on the principal surface of the sapphire substrate, the mask layer including a first side surface portion and a second side surface portion sandwiching each of the exposed regions in a direction parallel to the c-axis of the sapphire substrate forming a buffer layer on the plurality of exposed regions of the principal surface and the mask layer by using a nitride semiconductor; and epitaxially growing a nitride semiconductor layer on the buffer layer. In a cross section parallel to an m-axis and the c-axis of the sapphire substrate, a point at which the first side surface portion of the mask layer meets the principal surface of the sapphire substrate is defined as point A, a point at which the second side surface portion of the mask layer meets the principal surface of the sapphire substrate is defined as point B, a point at which the first side surface portion intersects a straight line passing through point B and forming an angle 58°−φ with the principal surface is defined as point C, a distance between a straight line passing through point C and perpendicular to the principal surface and a straight line passing through point B and perpendicular to the principal surface is defined as W, a height of the first side surface portion is defined as H, and H≧W·tan(58°−φ).

### First Embodiment

An example of an embodiment of the disclosure will now be described with reference to the drawings.

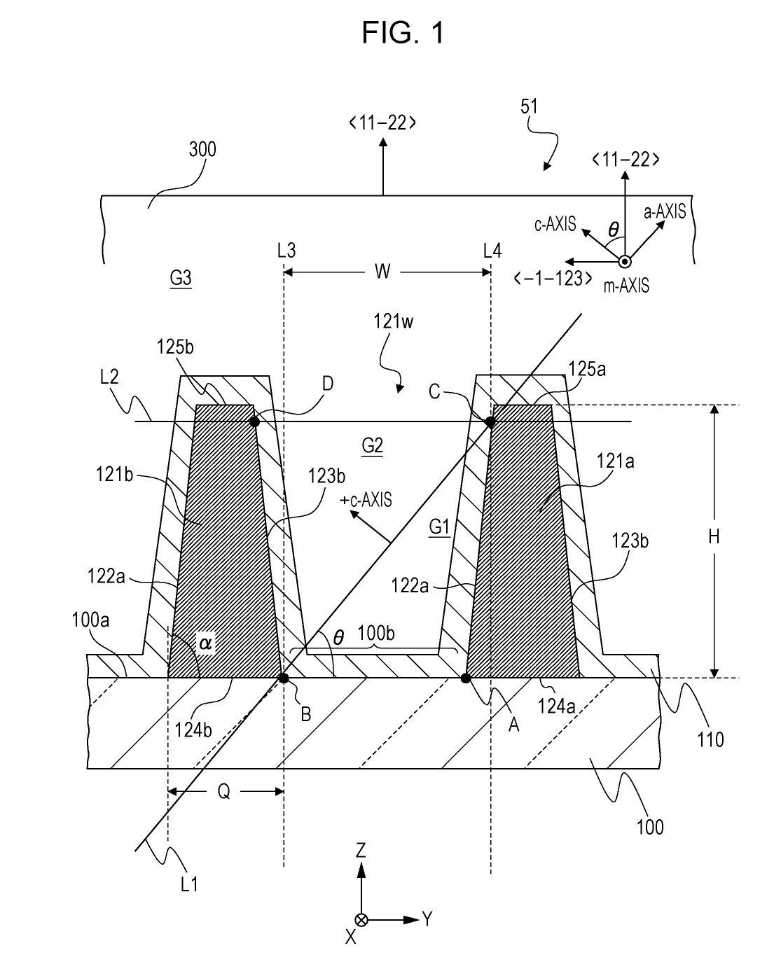

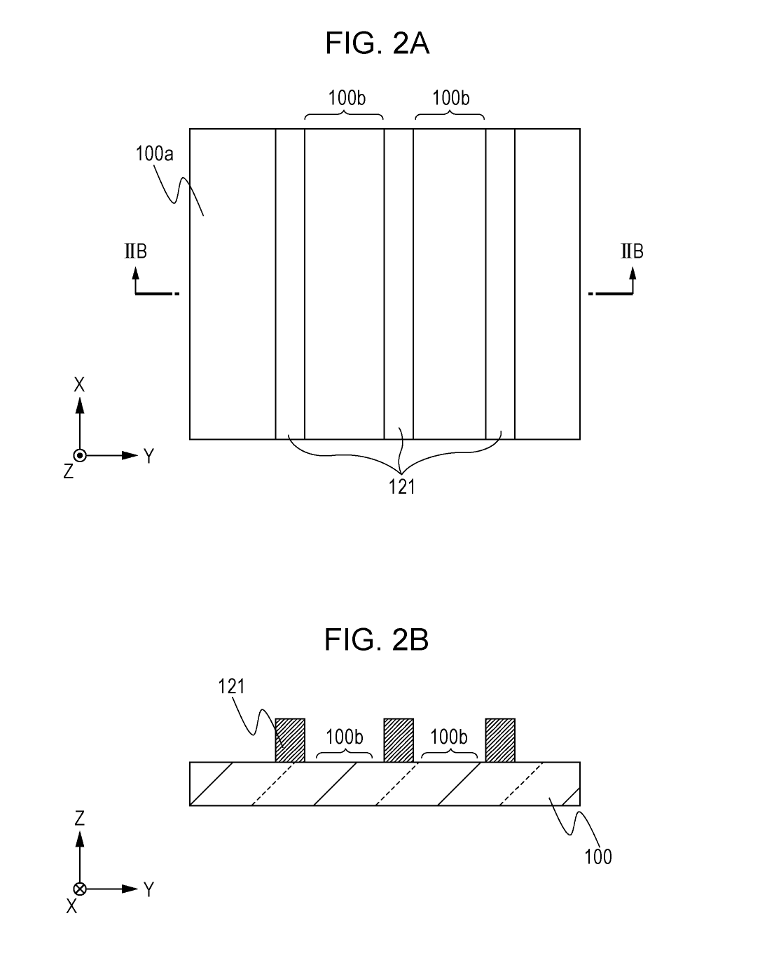

FIG. 1 is a cross-sectional view of a nitride semiconductor multilayer structure according to a first embodiment. As illustrated in FIG. 1, a nitride semiconductor multilayer structure 51 includes a substrate 100, a buffer layer 110, a mask layer 121 (FIG. 2A), and a nitride semiconductor layer 300. Specific examples of respective components are described in detail below.

### Substrate 100

The substrate 100 is a sapphire substrate having a principal surface 100a which is an m plane. In this disclosure, the term “m plane” refers to the (1-100) plane and planes equivalent thereto and planes having an off-angle of 10° or less with respect these planes. Examples of the planes that are equivalent to the (1-100) plane include the (−1100) plane, the (01-10) plane, the (0-110) plane, the (10-10) plane, and the (−1010) plane. In FIG. 1, the normal line of the principal surface 100a of the substrate 100 is coincident with the m-axis and the off-angle of the principal surface with respect to the c-axis is 0°. In other words, in FIG. 1, the Y-axis is the c-axis of the sapphire substrate, the Z-axis is the m-axis of the sapphire substrate, and the X-axis is the a-axis of the sapphire substrate. The sapphire substrate may be an m-plane substrate having an off-angle with respect to the c-axis. In particular, the sapphire substrate may have a principal surface whose m-axis is tilted by an angle of 0° or more and 10° or less in the c-axis direction from the normal line direction of the principal surface 100a. In this disclosure, a principal surface having such an off-angle may also be referred to as an “m plane”.

The substrate 100 may be a nitride semiconductor substrate. In such a case, the <1-100> direction of the substrate 100 is coincident with the X-axis, the <11-2-3> direction of the substrate 100 is coincident with the Y-axis, and the <11-22> direction of the substrate 100 is coincident with the Z-axis. The Z-axis is parallel to the stacking direction of the nitride semiconductor multilayer structure 51 and the X-axis and the Y-axis are each orthogonal to the stacking direction.

The substrate 100 composed of a nitride semiconductor may have a principal surface tilted by an angle of 0° or more and 10° or less. In such a case, the normal line of the principal surface is tilted by an angle in the range of 0° or more and 10° or less in the +c-axis direction from the <11-22> axis. It should be noted here that when the normal line of the principal surface is tilted by 10° in the +c-axis direction from the <11-22> axis, the principal surface is substantially equivalent to the (11-23) plane.

### Mask Layer 121

The mask layer 121 is formed on the principal surface 100a of the substrate 100. FIG. 2A is a plan view of the mask layer 121 formed on the principal surface 100a of the substrate 100. FIG. 2B is a cross-sectional view taken along line IIB-IIB in FIG. 2A. Referring to FIGS. 1, 2A, and 2B, the mask layer 121 has a pattern that exposes a plurality of regions 100b of the principal surface 100a. In this embodiment, the mask layer 121 has a striped structure. The striped structure has a pattern in which rod-shaped unit patterns extending in the X direction are arranged side-by-side while being spaced from one another in the Y direction at particular intervals. As illustrated in FIG. 1, the mask layer 121 includes a first side surface portion 122a and a second side surface portion 123b that sandwich each exposed region 100b. In FIG. 1, two adjacent unit patterns 121a and 121b are illustrated. Of the side surfaces of the unit pattern 121a, the side surface facing the unit pattern 121b is the first side surface portion 122a. Of the side surfaces of the unit pattern 121b, the side surface facing the unit pattern 121a is the second side surface portion 123b. An opening 121w is formed by the adjacent unit pattern 121a and unit pattern 121b. The opening 121w exposes the region 100b of the principal surface 100a of the substrate 100. In this disclosure, this region 100b may also be referred to as an “exposed region”.

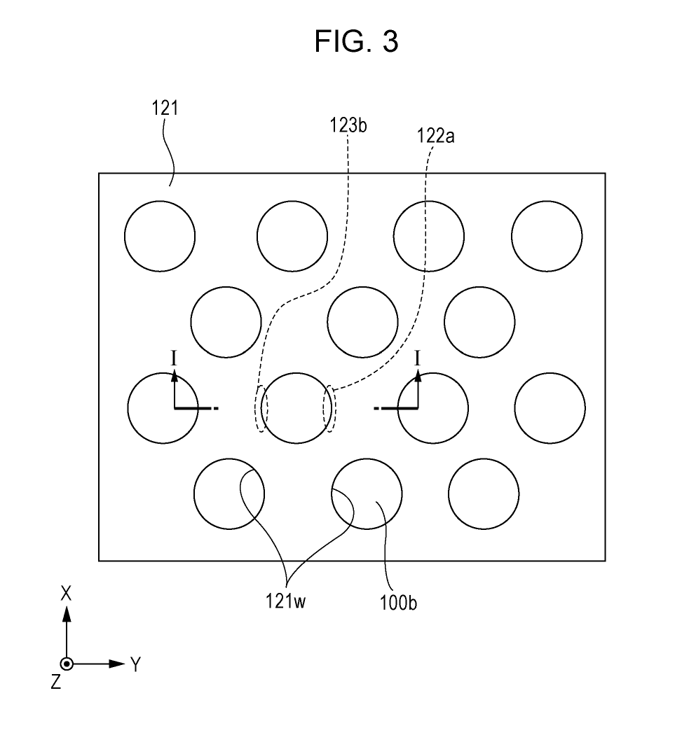

The pattern of the mask layer 121 is not limited to one having a striped structure. FIG. 3 is a plan view of an example of a mask layer 121 having a different pattern. As illustrated in FIG. 3, the mask layer 121 may have a plurality of independent openings 121w. The term “independent” means that the openings 121w are not connected to each other. Although the openings 121w illustrated in FIG. 3 have a round shape, the openings 121w may have any other shape, such as a square shape, an oblong shape, a polygonal shape, or an ellipsoidal shape. The region 100b of the principal surface 100a is exposed at the bottom portion of the opening 121w. The arrangement of the openings 121w is not particularly limited as long as the openings 121w are arranged in a two-dimensional pattern.

As illustrated in FIG. 3, in the mask that defines the openings 121w, the portions facing the Y direction constitute the first side surface portion 122a and the second side surface portion 123b. The cross-section taken along line I-I in FIG. 3 has the same structure as one illustrated in FIG. 1.

The mask layer 121 may be composed of any material. After the mask layer 121 has been formed, a buffer layer 110 and a nitride semiconductor layer 300 that cover the mask layer 121 are formed. Accordingly, the mask layer 121 may be composed of a material that does not undergo changes in shape or composition by the temperature and atmosphere for forming the buffer layer 110 and the nitride semiconductor layer 300. For example, the mask layer 121 may be composed of a dielectric inorganic material such as silicon oxide or silicon nitride. The mask layer 121 may be composed of silicon oxide, for example.

Referring to FIG. 1, in this embodiment, the unit pattern 121a and the unit pattern 121b have a trapezoidal shape at a plane that includes the Y-axis and the Z-axis. The unit pattern 121a includes an upper surface 125a, a bottom surface 124a, a second side surface portion 123b, and a first side surface portion 122a. Similarly, the unit pattern 121b includes an upper surface 125b, a bottom surface 124b, a second side surface portion 123b, and a first side surface portion 122a.

The angle α formed between the first side surface portion 122a and the principal surface 100a may be 60° or more and 90° or less. The angle α formed between the second side surface portion 123b and the principal surface 100a may also be 60° or more and 90° or less. The angle α is defined as an inner angle of the trapezoidal shape. At an angle α less than 60°, the width of the unit pattern of the mask layer 121 increases and thus the area of the principal surface 100a covered with the mask layer 121 increases. A mask layer 121 having an angle α larger than 90° may be difficult to manufacture.

As illustrated in FIG. 1, in a cross-section taken parallel to the Y-axis and the Z-axis, the point at which the first side surface portion 122a of the mask layer 121 meets the principal surface 100a of the substrate 100 is defined as point A. The point at which the second side surface portion 123b of the mask layer 121 meets the principal surface 100a of the substrate 100 is defined as point B. The point at which the first side surface portion 122a intersects a straight line L1 passing through point B and forming an angle θ with the principal surface 100a is defined as point C.

The distance between a straight line L4 passing through point C and perpendicular to the principal surface 100a and a straight line L3 passing through point B and perpendicular to the principal surface 100a is defined as W. The point at which the second side surface portion 123b intersects a straight line L2 passing through point C and parallel to the principal surface 100a is defined as point D. The height of the first side surface portion 122a is defined as H.

The height H, the distance W, and the angle θ satisfy the following relationships (1) and (2); in other words, the mask layer 121 has a shape that satisfies the relationships (1) and (2):

H≧W·tan θ (1)

48°≦θ≦58° (2)

It should be noted here that when the principal surface of the substrate 100 has an off-angle φ, θ equals 58°−φ, as described later.

### Buffer Layer 110

The buffer layer 110 is disposed on the exposed regions 100b of the principal surface 100a and the mask layer 121. The buffer layer 110 is composed of a nitride semiconductor. In this disclosure, the term “nitride semiconductor” refers to a semiconductor represented by compositional formula AlₓIn_{y}Ga_{z}N (where 0≦x<1, 0≦y<1, 0<z≦1, and x+y+z=1).

The nitride semiconductor may contain an impurity element for imparting conductivity to the semiconductor. For example, Si or Ge may be contained for the n-type conductivity control or Mg may be contained for the p-type conductivity control. Boron (B) may be contained to control the lattice constant.

In the buffer layer 110, a portion located on the exposed region 100b of the principal surface 100a and a portion located on the mask layer 121 (e.g. the unit patterns 121a and 121b in FIG. 1) have crystal structures different from each other. To be specific, in the buffer layer 110, the portion located on each exposed region 100b of the principal surface 100a has a single crystal structure whereas the portion located on the mask layer 121 (e.g. unit pattern 121a or 121b) has a polycrystal structure or an amorphous structure. In particular, the portion located on the exposed region 100b of the principal surface 100a has a crystal structure in which the (11-22) plane is the principal surface. This can be confirmed by the fact that the crystal growth process used in this embodiment is the same as the crystal growth process of Comparative Example 1 described below. In the buffer layer 110, the portion on the exposed region 100b of the principal surface 100a is formed by epitaxial growth and reflects the crystal structure of the substrate 100. In contrast, in the buffer layer 110, the portion on the mask layer 121 has an amorphous structure or a crystal structure formed not through epitaxial growth. Accordingly, the crystal structures of these portions differ as described above.

The buffer layer 110 may be uniformly formed on the mask layer 121 and the exposed regions 100b of the principal surface 100a so as to have a substantially uniform thickness and a substantially uniform morphology. For example, a buffer layer 110 may be grown at a relatively low temperature. The temperature may be, for example, 400° C. or more and 800° C. or less or may be 400° C. or more and 650° C. or less. When grown at a low temperature, the raw materials undergo less migration and a buffer layer 110 that includes portions with different crystal structures reflecting the crystal structures of the underlying materials can be formed.

The nitride semiconductor layer constituting the buffer layer 110 may contain aluminum (Al). The nitride semiconductor layer constituting the buffer layer 110 can turn into a material, such as AlN or a ternary alloy such as AlGaN, more resistant to migration than GaN if the nitride semiconductor layer contains aluminum.

In this embodiment, the buffer layer 110 may be formed only on the surface of the substrate 100, that is, the regions 100b. The buffer layer 110 formed on the surface of the mask layer 121 may be removed or the buffer layer 110 may be intentionally formed only on the regions 100b. For example, a buffer layer 110 may be formed and heated in a growth furnace and then the polycrystal-like buffer layer formed on the mask layer 121 may be removed by a heat treatment. Alternatively, the buffer layer 110 may be formed only on the regions 100b by a mass-transport method or the like.

The buffer layer 110 may have a thickness of 1 nm or more and 500 nm or less on the regions 100b. The buffer layer 110 located on the regions 100b has a single crystal structure. The buffer layer 110, compared to the surface of the substrate 100, promotes nucleation of nitride semiconductor crystals, and accelerates selective growth of the nitride semiconductor. Accordingly, the thickness of the buffer layer 110 may be small but in the range that can promote nucleation during selective growth. The thickness of the buffer layer 110 also relates to the crystallinity of the nitride semiconductor layer 300 and may be appropriately selected. For example, the thickness of the buffer layer 110 may be 20 nm or more and 200 nm or less.

### Nitride Semiconductor Layer 300

The nitride semiconductor layer 300 is located on the buffer layer 110 and composed of a nitride semiconductor. Referring to FIG. 1, the nitride semiconductor layer 300 is in contact with the buffer layer 110 on the first side surface portion 122a and the second side surface portion 123b of the mask layer 121 and the buffer layer 110 that lies between the first side surface portion 122a and the second side surface portion 123b.

As illustrated in FIG. 1, a first region G1, a second region G2, and a third region G3 are defined in a cross-section that includes the Y-axis and the Z-axis. The first region G1 is defined by the principal surface 100a, the first side surface portion 122a, and a straight line L1 connecting point B and point C. The second region G2 is defined by the second side surface portion 123b, the straight line L1, and a straight line L2 passing through point C and parallel to the principal surface 100a. The third region G3 is a region above the straight line L2.

As described in detail below, the nitride semiconductor layer 300 is an epitaxially grown layer that reflects the crystallinity of the buffer layer 110 in the portion that lies on the exposed region 100b. In particular, the nitride semiconductor layer 300 has a single crystal structure in which the principal surface is the (11-22) plane and is oriented in the <11-22> direction. Since the normal line of the upper surface of the nitride semiconductor layer 300 is parallel to the Z-axis, the <11-22> direction of the nitride semiconductor layer 300 is parallel to the Z-axis. The m-axis of the nitride semiconductor layer 300, that is, the <1-100> direction, is parallel to the X-axis and the <−1-123> direction of the nitride semiconductor layer 300 is parallel to the Y-axis.

Note that in the case where the substrate 100 is an m-plane sapphire substrate having an off-angle φ, the <11-22> direction of the nitride semiconductor layer 300 is tilted from the Z-axis by an angle φ in the −c-axis direction. In this case, the <1-100> direction is substantially parallel to the X-axis, and the <−1-123> direction is tilted from the Y-axis by an angle φ in the −c-axis direction.

In the cross section illustrated in FIG. 1, the c-axis of the nitride semiconductor layer 300 is perpendicular to the straight line L1 and the a-axis is parallel to the straight line L1. The nitride semiconductor has no centrosymmetry with respect to the c-axis direction. The c-axis direction illustrated in FIG. 1 indicates the +c-axis direction.

Note that in the case where the substrate 100 is an m-plane sapphire substrate having an off-angle φ, the c-axis of the nitride semiconductor layer 300 is perpendicular to the straight line L1 and the a-axis is parallel to the straight line L1. In other words, the straight line L1 is set to be perpendicular to the c-axis of the nitride semiconductor layer 300 and the a-axis is set to be parallel to the straight line L1 when the straight line L1 is defined as a straight line that forms an angle θ of 58°−φ with the principal surface 100a where φ represents an off-angle of the m-plane sapphire substrate.

When the shape of the mask layer 121 at any cross-section that includes the Y-axis and the Z-axis satisfies the relationships (1) and (2) described before, the first region G1, the second region G2, and the third region G3 of the nitride semiconductor layer 300 exhibit different dislocation densities. In particular, the nitride semiconductor layer 300 exhibits a higher dislocation density in the first region G1 than in the second region G2. The second region G2 and the third region G3 of the nitride semiconductor layer 300 have substantially the same dislocation density. For example, the nitride semiconductor layer 300 has a dislocation density of 10¹⁰ cm⁻² or more in the first region G1 and a dislocation density of 10⁸ cm⁻² or lower in the second region G2 and the third region G3. This is because dislocations that occur in the initial stage of formation of the nitride semiconductor layer 300 are blocked or suppressed by the mask layer 121. The relationship between the formation of the nitride semiconductor layer 300 and the dislocation density is described below in detail.

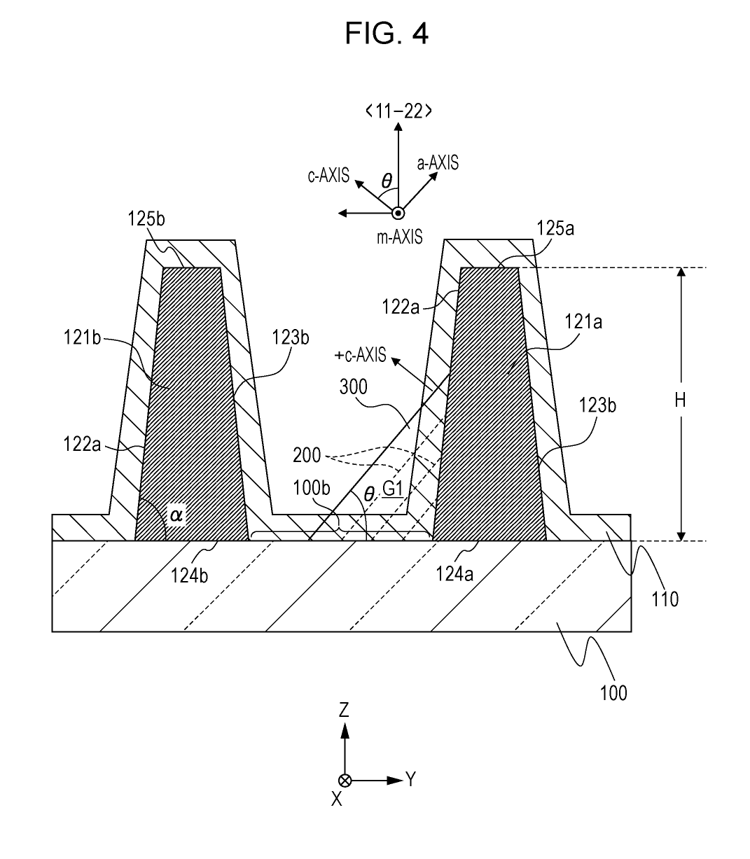

As illustrated in FIG. 4, during the course of epitaxially growing a nitride semiconductor layer 300 on a buffer layer 110, raw materials are preferentially decomposed and nucleation occurs in the buffer layer 110 that lies on the exposed regions 100b. In contrast, nucleation rarely occurs in the buffer layer 110 in the portion that lies on the mask layer 121. This is due to the difference in crystal structure in the buffer layer 110 as described above.

The nitride semiconductor layer 300 is epitaxially grown on the buffer layer 110 on the principal surface 100a of the substrate 100, in other words, a sapphire substrate with an m-plane principal surface. The epitaxial growth layer grows in the +c-axis direction. As a result of growth, a nitride semiconductor layer 300 having the (11-22) plane as the principal surface is obtained.

In the case where the substrate 100 is an m-plane sapphire substrate, the nitride semiconductor layer 300 formed in the first region G1 contains many dislocations 200 due to the lattice mismatch between the m-plane sapphire substrate and the buffer layer 110 and the lattice mismatch between the buffer layer 110 and the nitride semiconductor layer 300. In other words, the substrate 100 causes dislocations 200 to occur in the first region G1. In FIG. 4, the dislocations 200 are indicated by broken lines. These broken lines are also referred to as dislocation lines. The density of the dislocations 200 is 10¹⁰ cm⁻² or more.

The dislocations 200 have a tendency to orthogonally intersect the c-axis of the nitride semiconductor layer 300. In other words, the dislocations 200 are parallel to the c plane of the nitride semiconductor layer 300 and tend to be formed within the c plane. In such a case, the c plane is a slip plane. In this disclosure, the “dislocation” may also refer to stacking faults. Stacking faults are a type of planar defects and can be formed in the c-plane. In contrast, dislocations are a type of linear defects. As disclosed in U.S. Pat. No. 6,809,351, dislocations may be bended depending on the propagation direction and the facet faces. In contrast, the stacking faults are not bended. In this disclosure, the “dislocations” may also refer to bended dislocations caused by the propagation direction or the facet faces.

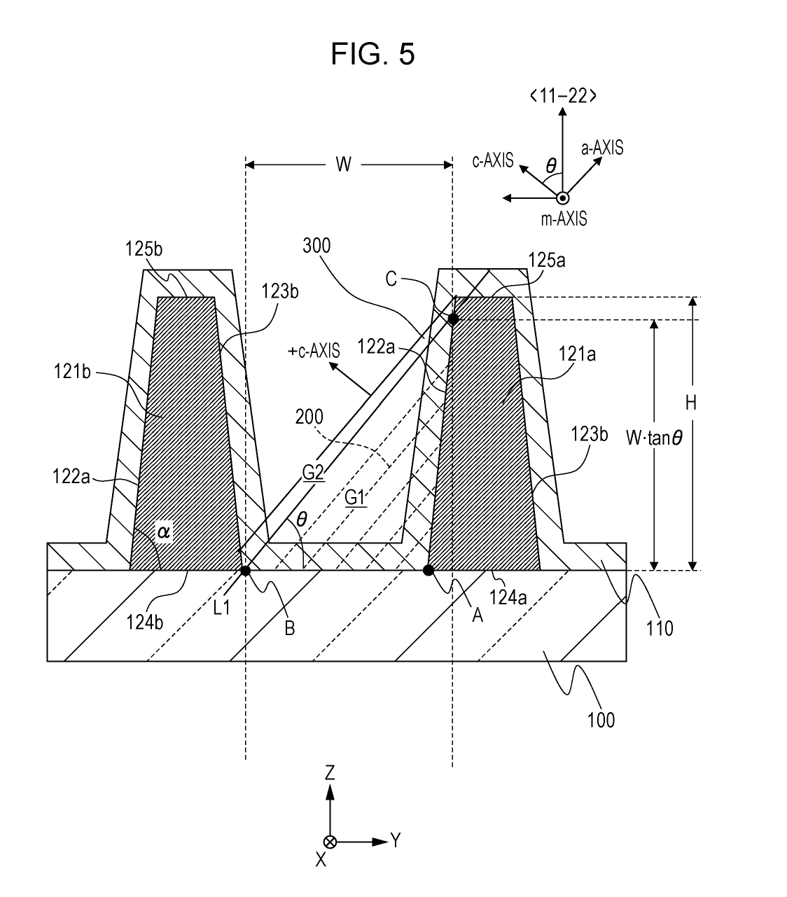

As the nitride semiconductor layer 300 keeps growing, the nitride semiconductor layer 300 exceeds the straight line L1 as illustrated in FIG. 5. The part of the nitride semiconductor layer 300 that has exceeded the straight line L1 is located in the second region G2. The nitride semiconductor layer 300 located in the second region G2 has a lower dislocation density. It is presumably due to the three reasons described below.

Reason A: The second region G2 is not in contact with the substrate 100 that causes dislocations 200.

Reason B: The dislocations 200 in the first region G1 orthogonally intersect the c-axis of the nitride semiconductor layer 300. Accordingly, the dislocations 200 in the first region G1 do not appear in the second region G2 epitaxially grown in a direction parallel to the c-axis of the nitride semiconductor layer 300. In other words, the dislocations 200 in the first region G1 do not continue into the second region G2.

Reason C: The buffer layer 110 on the mask layer 121 rarely causes dislocations.

As described above, the nitride semiconductor layer 300 in the second region G2 is grown to have a low dislocation density. In particular, as described above, the nitride semiconductor layer 300 has a dislocation density of 10⁸ cm⁻² or less in the second region G2, for example.

The nitride semiconductor layer 300 is then epitaxially grown in the third region G3. During this process, the first region G1 is partitioned by the first side surface portion 122a in a freely taken cross-section including the Y-axis and the Z-axis since the mask layer 121 satisfies the relationships (1) and (2) and thus the first region G1 does not substantially come into contact with the third region G3. In other words, in a freely taken cross section that includes the Y-axis and the Z-axis, the first region G1 and the second region G2 are located within an opening of the mask layer 121. This means that the dislocations 200 in the first region G1 of the nitride semiconductor layer 300 are spatially separated from the third region G3 and propagation of the dislocations 200 does not occur in the nitride semiconductor layer 300 grown in the third region G3. It should be understood that, when the cross-section including the Y-axis and the Z-axis is observed closely, the first region G1 comes into contact with the third region G3 at a straight line passing through point C and parallel to the X-axis. This straight line is a mathematical straight line and has no substantial area that causes propagation of the dislocations 200 described above. Accordingly, the dislocations 200 in the first region G1 do not continue into the third region G3.

The value of W is, for example, 100 nm or more and 5 μm or less. The width of the exposed region 100b in the y direction is, for example, 100 nm or more and 5 μm or less.

As described above, the nitride semiconductor layer 300 is grown in the second region G2 and then in the third region G3. Accordingly, the third region G3 has a low dislocation density as in the second region G2.

The normal line of the growth surface of the nitride semiconductor layer 300 in the first region G1 lies parallel to the +c-axis direction. Accordingly, in the second region G2, the epitaxial growth does not occur in the −c-axis direction. Similarly, the epitaxial growth does not occur in the −c-axis direction in the third region G3. The layer epitaxially grown in the +c-axis direction has higher surface flatness and higher crystallinity than the layer epitaxially grown in the −c-axis direction.

As described above, the mask layer 121 inhibits continuation of the dislocations 200 in the first region G1 of the nitride semiconductor layer 300 into the second region G2 and the third region G3. Accordingly, the nitride semiconductor layer 300 exhibits a low dislocation density of, for example, 10⁸ cm⁻² or less in the second region G2 and the third region G3. Thus, even in the case where another nitride semiconductor layer is formed on the nitride semiconductor layer 300 to prepare a semiconductor device, the dislocation density of that other nitride semiconductor layer can be reduced. In other words, a semiconductor device in which another nitride semiconductor layer formed on the nitride semiconductor layer 300 can exhibit excellent properties.

As indicated by Reference Example 1 described later, in the case where an m-plane sapphire substrate having an off-angle of 5° with respect to the c-axis is used as the substrate 100, the nitride semiconductor layer 300 having a (11-22) principal surface has an angle θ of 53° (=58°−5°). As indicated by Reference Example 2, in the case where an m-plane sapphire substrate having an off-angle of 10° with respect to the c-axis is used as the substrate 100, the nitride semiconductor layer 300 having a (11-22) principal surface has an angle θ of 48° (=58°−10°). When θ=48°, the nitride semiconductor layer 300 can also be described as having a (11-23) principal surface. Accordingly, the angle θ is within the range of 48° or more and 58° or less.

That is, when an m-plane sapphire substrate having an off-angle φ with respect to the c-axis is used, the angle θ is 58°−φ. Since the angle φ is in the range of 0° or more and 10° or less, the angle θ falls within the range of 48° or more and 58° or less. Accordingly, the relationships (1) and (2) described before indicate the same range as the range indicated by formulae (3) and (4) below:

H≧W·tan(58°−φ) (3)

0°≦φ≦10° (4)

In the case where an m-plane sapphire substrate having an off-angle of φ with respect to the c-axis is used as the substrate 100, the actual principal surface of the nitride semiconductor layer is inclined from the (11-22) plane by an angle φ. In particular the <11-22> direction of the nitride semiconductor layer is tilted by an angle φ in the c-axis direction with respect to the normal line direction of the principal surface. In this disclosure, a nitride semiconductor layer that has such an off-angle is also referred to as a nitride semiconductor layer having a (11-22) principal surface for the sake of convenience.

As illustrated in FIG. 1, the angle θ is defined as an angular difference between the principal surface of the nitride semiconductor and the c plane. As apparent from the relationship (1), the height H of the mask layer 121 needed to obtain the effects of this embodiment is dependent on θ. For example, in the case of a nitride semiconductor layer having a (11-22) principal surface in which the opening 121w of the mask (in other words, W in relationship (1)) is 2 μm and the angular difference relative to the c plane is θ=58° is used, the required height H will be 3.2 μm or more. In other words, it is necessary to form a mask layer 121 having a relatively high aspect ratio of 1.6 or more to selective grow a nitride semiconductor layer.

In this disclosure, the aspect ratio of a mask layer refers to the ratio of a height H of the mask layer to the width W of the opening of the mask layer.

Typically, in selective growth conducted by using a mask structure having a high aspect ratio, the raw materials rarely reach the substrate surface and selective growth may be inhibited or in-plane nonuniformity may occur. Accordingly, from the viewpoint of performing selective growth, the aspect ratio may be decreased within the range that satisfies relationships (1) and (2).

The mask height H can be decreased if a nitride semiconductor layer 300 having a semi-polar surface with a small angle θ can be used.

For example, when θ=48°, the required H is 2.2 μm and the aspect ratio can be decreased to about 1.

The results of investigation conducted on nitride semiconductor layer structures having a (11-22) principal surface in Example 1, Reference Example A, and Reference Example B are described in the later section. In Reference Example 1 and Reference Example 2, the results of investigation conducted on nitride semiconductor multilayer structures based on the (11-22) plane in which the angle θ includes an off angle up to 10° are described. The description provided above and the description of experimental results presented later will clarify that the same effects as those described above can be obtained by applying the above-described structure and method of this embodiment to a nitride semiconductor layer structure having a semi-polar surface.

Note that a nitride semiconductor layer structure having a semi-polar surface typically has a tilted c-plane in a nitride semiconductor layer and dislocations and defects present in the crystals tend to be mainly formed in the c plane. For example, the mask layer described above may be used on a nitride semiconductor multilayer structure having, as a principal surface, the (11-24) plane near θ=39° or a nitride semiconductor multilayer structure having, as a principal surface, the (30-31) or (20-21) plane that is the c plane tilted in the m-axis direction.

However, when a mask structure of this embodiment is used for a nitride semiconductor layer having a (20-21) principal surface, φ is 75° and thus the height H of the mask structure that can yield the same effects as those of this embodiment is 7.5 μm or more (in the case where W=2 μm). In other words, a mask structure having a significantly high aspect ratio of 3.7 is necessary.

### Manufacturing Method

A nitride semiconductor multilayer structure according to this embodiment can be manufactured through a typical method of epitaxially growing a nitride semiconductor layer having a (11-22) principal surface on a substrate. For example, refer to Philippe Vennegues et al., Study of the epitaxial relationships between III-nitrides and M-plane sapphire, Journal of Applied Physics, vol. 108, page 113521 (2010) for the method for epitaxially growing a nitride semiconductor layer having a (11-22) principal surface on an m-plane sapphire substrate. An example of a method for manufacturing a nitride semiconductor multilayer structure according to this embodiment is described in detail in Examples below.

### Second Embodiment

The nitride semiconductor multilayer structure according to the first embodiment may be used as a nitride semiconductor bulk substrate of a light-emitting device.

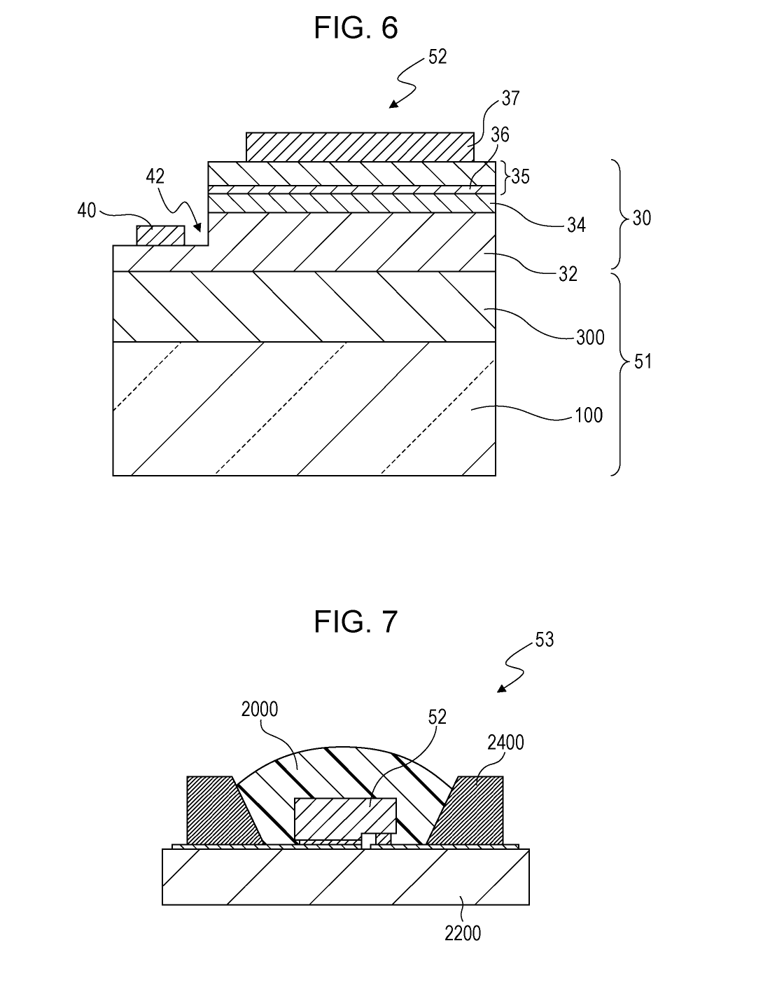

FIG. 6 is a schematic diagram of a light-emitting device 52 according to a second embodiment. The nitride semiconductor multilayer structure 51 of the first embodiment may be used in the light-emitting device 52 illustrated in FIG. 6.

The light-emitting device 52 includes a nitride semiconductor multilayer structure 51 and a nitride semiconductor multilayer structure 30 disposed on the nitride semiconductor multilayer structure 51. In FIG. 6, the mask layer 121 and the buffer layer 110 of the nitride semiconductor multilayer structure 51 are not illustrated for the sake of simplicity of the figure. The nitride semiconductor multilayer structure 30 includes an n-type nitride semiconductor layer 32, a p-type nitride semiconductor layer 35, and an active layer 34 sandwiched between the n-type nitride semiconductor layer 32 and the p-type nitride semiconductor layer 35. An undoped nitride semiconductor layer 36 may be formed on the active layer 34-side of the p-type nitride semiconductor layer 35.

A recess 42 that exposes a part of the n-type nitride semiconductor layer 32 is formed in the nitride semiconductor multilayer structure 30. An n-side electrode 40 in contact with and electrically connected to the n-type nitride semiconductor layer 32 is formed at the bottom of the recess 42. A p-side electrode 37 is in contact with and electrically connected to the p-type nitride semiconductor layer 35.

The nitride semiconductor multilayer structure 30 is composed of AlₓGa_{y}In_{z}N (0≦x≦1, 0≦y≦1, 0≦z≦1, x+y+z=1). Silicon (Si) may be used as the n-type dopant and magnesium (Mg) may be used as the p-type dopant. The nitride semiconductor multilayer structure 30 can be formed by any of various epitaxial growth techniques as with the nitride semiconductor multilayer structure 51.

The principal surface of each semiconductor layer in the nitride semiconductor multilayer structure 30 has the same plane orientation as the nitride semiconductor layer 300 of the nitride semiconductor multilayer structure 51 and has a low dislocation density. Thus, according to this embodiment, a light-emitting device that includes an active layer with excellent crystallinity can be realized.

### Third Embodiment

The light-emitting device 52 according to the second embodiment can be directly used as a light source. Alternatively, the light-emitting device according to the second embodiment can also be used in combination with a fluorescent substance-containing resin for wavelength conversion so that the light-emitting device can be used in a light source with a wider wavelength band region.

FIG. 7 is a schematic diagram of an example of a light source 53. The light source 53 illustrated in FIG. 7 includes the light-emitting device 52 according to the second embodiment and a resin layer 2000 containing dispersed phosphors that converts light emitted from the light-emitting device 52 into light of a different wavelength band region. The light-emitting device 52 is mounted on a support member 2200 with a wiring pattern formed on the surface. A reflection member 2400 is arranged on the support member 2200 so as to surround the light-emitting device 52. The resin layer 2000 is formed so as to cover the light-emitting device 52.

### Experimental Results Related to First Embodiment

A nitride semiconductor multilayer structure according to the first embodiment was fabricated and the properties were measured. The results are described below.

### Example 1

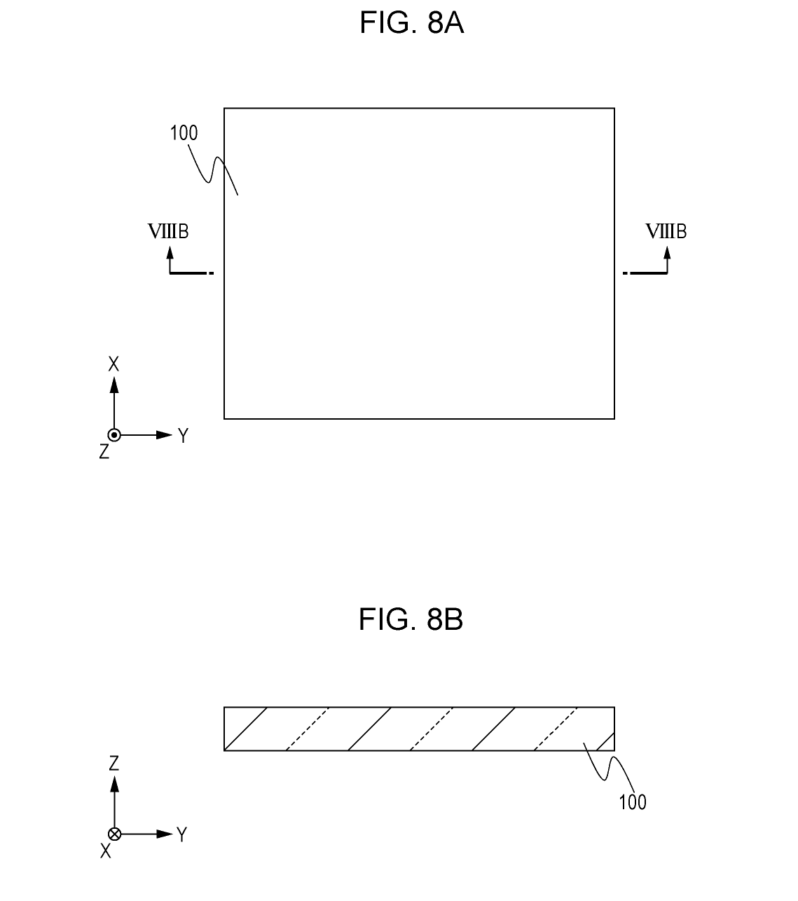

As illustrated in FIGS. 8A and 8B, a substrate 100 was first prepared. The substrate 100 was an m-plane sapphire substrate and was available from Kyocera Corporation. FIG. 8A is a plan view of the substrate 100. FIG. 8B is a cross-sectional view of the substrate 100 taken along line VIIIB-VIIIB in FIG. 8A.

The substrate 100 had a diameter of about 2 inches and a thickness of 0.43 mm. The substrate 100 had an off-angle of 0.1° or less. The tilt direction of the off-angle was the c-axis direction of the substrate 100.

Washing m-Plane Sapphire Substrate

The substrate 100 was washed for 10 minutes with a cleaning solution heated to 100° C. The cleaning solution was a sulfuric acid/phosphoric acid (1:1) (volume basis) mixture. The substrate 100 was then washed with water.

### Forming Mask Layer

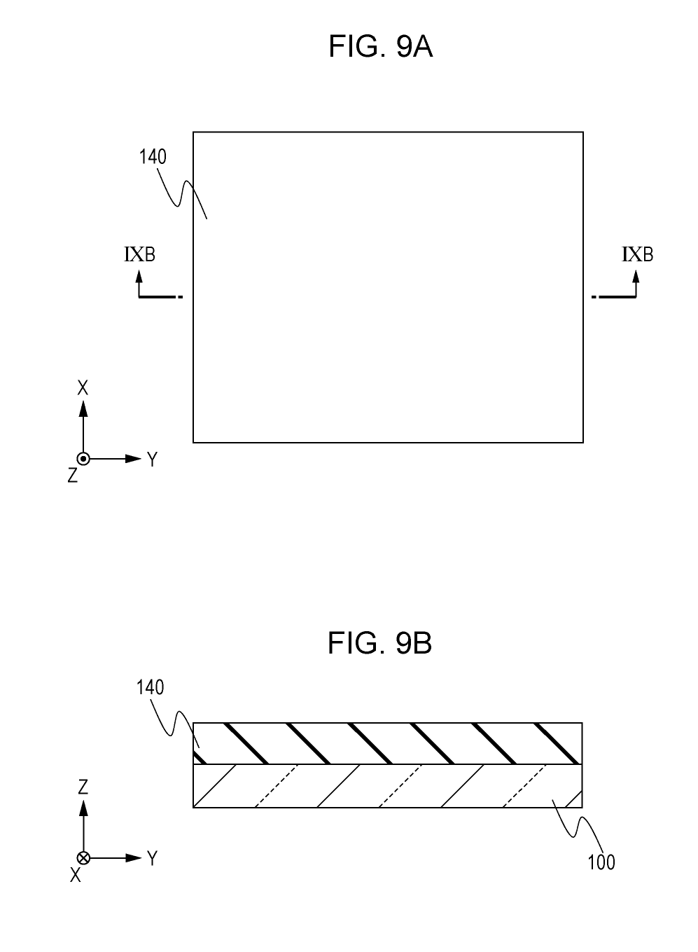

As illustrated in FIGS. 9A and 9B, a SiO₂ film 140 having a thickness of about 3.5 μm was formed on the substrate 100 by a plasma chemical vapor deposition (CVD) method.

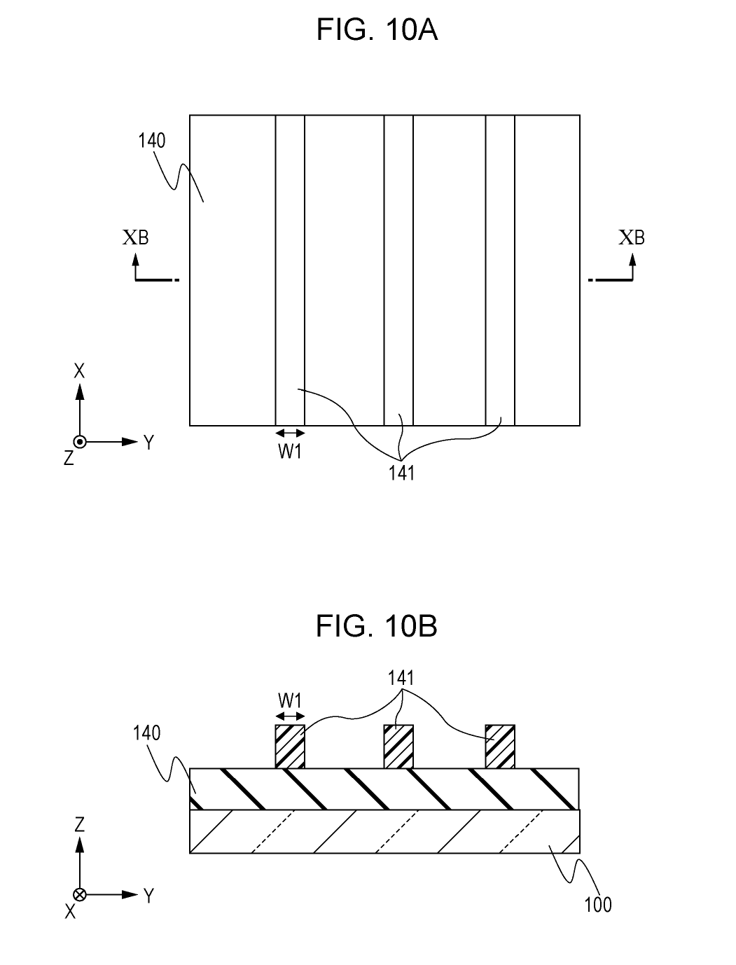

As illustrated in FIGS. 10A and 10B, strip-shaped photoresist layers 141 were formed on the SiO₂ film 140. The photoresist layers 141 were arranged to be parallel to one another. The longitudinal direction of each photoresist layer 141 was parallel to the a-axis of the substrate 100. In other words, the longitudinal direction of each photoresist layer 141 was parallel to the X-axis. The width W1 of each photoresist layer 141 was 2 μm. The interval between two adjacent photoresist layers 141 was 2 μm.

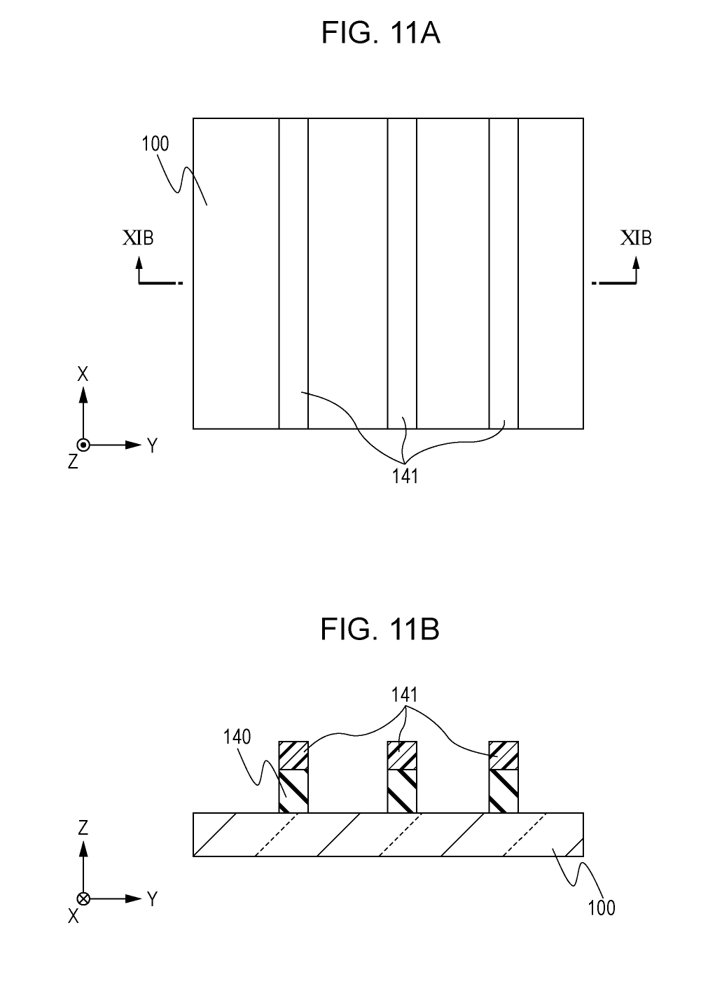

As illustrated in FIGS. 11A and 11B, the SiO₂ film 140 was partly dry-etched so as to etch away portions not covered with the photoresist layers 141. Then the photoresist layers 141 were removed. As a result, a mask layer 121 having a plurality of strip-shaped patterns composed of SiO₂ was formed on the substrate 100, as illustrated in FIGS. 2A and 2B.

FIGS. 2A and 2B clearly illustrate that the strip-shaped patterns of the mask layer 121 were parallel to the a-axis of the substrate 100. In other words, the strip-shaped patterns of the mask layer 121 were parallel to the X-axis. The width W1 of each patterns of mask layer 121 was 2 μm. The interval between adjacent two patterns of the mask layer 121 was 2 μm. The height H of each pattern of mask layer 121 was about 3.5 μm. The angle α was about 75°.

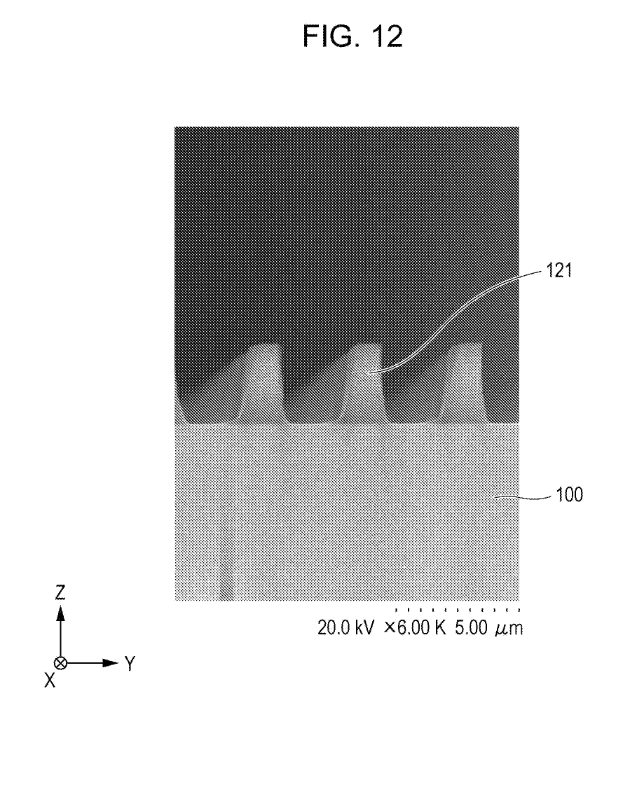

FIG. 12 is a photograph of a cross section of a substrate 100 that has strip-shaped patterns of the mask layer 121 on the surface according to Example 1.

In the case where a nitride semiconductor layer 300 is epitaxially grown on the substrate 100, the nitride semiconductor layer 300 has a (11-22) principal surface. In other words, the normal line direction of the principal surface of the nitride semiconductor layer 300 is the <11-22> direction. As illustrated in FIG. 1, a nitride semiconductor layer 300 having a (11-22) principal surface is grown on a substrate 100. In such a case, the angle θ is 58°, as illustrated in FIG. 1.

Since the interval between two adjacent patterns of mask layer 121 is 2 μm, the height H of the mask layer 121 needs to be about 3.2 (=2×about 1.6) μm according to relationship (1): H≧W·tan θ. As described above, the height H of the mask layer 121 in Example 1 was about 3.5 μm.

### Growing Buffer Layer

The substrate 100 having the strip-shaped patterns of mask layer 121 thereon was loaded in a metal organic chemical vapor deposition (MOCVD) reactor. In the MOCVD reactor, hydrogen and nitrogen were used as carrier gas. During deposition, the substrate 100 was rotated at 3 rpm.

The substrate 100 was heated in the MOCVD reactor. As the temperature of the substrate 100 reached 1120° C., a heat treatment was performed for 10 minutes.

After the heat treatment, the substrate 100 was cooled. Five minutes elapsed after the substrate temperature reached 550° C.

Then only trimethyl aluminum (referred to as “TMA” hereinafter) was first applied to the m-plane sapphire substrate surface for 10 seconds and then ammonia gas was supplied. As a result, a buffer layer 110 composed of a nitride semiconductor composed of AlN was obtained.

The growth conditions of the buffer layer 110 used in this example are described in Table 1.

TABLE 1

| Conditions | Values | |
|---|---|---|
| TMA flow rate | 16 | μmol/min |
| Ammonia flow rate | 0.6 | L/min |
| Growth time for buffer layer 110 | 16 | minutes |
| Growth pressure | 13 | kPa |

| | |
|---|---|
| ammonia/TMA feed ratio (molar ratio) | About 1700 |

The thickness of the buffer layer 110 was set to about 200 nm. After growing the buffer layer 110 and after the substrate temperature reached 1020° C., one minute elapsed.

Subsequently, trimethyl gallium (hereinafter referred to as “TMG”) and ammonia were supplied to the MOCVD reactor and a nitride semiconductor layer 300 having a (11-22) principal surface was grown on the surface of the substrate 100. As a result, a nitride semiconductor multilayer structure composed of GaN was obtained. Table 2 indicates the growth conditions of the nitride semiconductor layer 300.

TABLE 2

| Conditions | Values | |
|---|---|---|
| TMG flow rate | 136 | μmol/min |
| Ammonia flow rate | 0.5 | L/min |
| Growth rate for nitride semiconductor layer 300 | 3 to 4 | μm/hour |
| Growth time for nitride semiconductor layer 300 | 1 | hour |
| Growth pressure | 13 | kPa |

| | |
|---|---|
| ammonia/TMG feed ratio (molar ratio) | About 160 |

The thickness of the nitride semiconductor layer 300 was about 4 to 5 μm.

### Reference Example A

Substantially the same experiment as in Example 1 was performed except that the buffer layer 110 indicated in Table 1 was not used and the following heating process was employed.

The substrate 100 was heated in a MOCVD reactor. As the temperature of the substrate 100 reached 500° C., supply of ammonia gas was started. It was presumed that this ammonia gas nitrided the surface of the substrate 100.

After the temperature of the substrate 100 reached 920° C., one minute elapsed.

Then TMG and ammonia were supplied to the MOCVD reactor and a nitride semiconductor layer 300 having a (11-22) principal surface was grown on the surface of the substrate 100. As a result, a nitride semiconductor multilayer structure composed of GaN was obtained. The conditions of the growth were the same as those indicated in Table 2 of Example 1.

### Reference Example B

The same experiment as one in Reference Example A was conducted except that the growth conditions indicated in Table 3 were employed instead of the growth conditions indicated in Table 2.

TABLE 3

| Conditions | Values | |
|---|---|---|
| TMG flow rate | 136 | μmol/min |
| Ammonia flow rate | 3.0 | L/min |
| Growth rate for nitride semiconductor layer 300 | 3 to 4 | μm/hour |
| Growth time for nitride semiconductor layer 300 | 1.5 | hours |
| Growth pressure | 66 | kPa |

| | |
|---|---|
| ammonia/TMG feed ratio (molar ratio) | About 985 |

### Comparative Example 1

The same experiment as one in Reference Example A was conducted except that the mask layer 121 was not formed. In other words, after the substrate 100 was washed, the nitride semiconductor layer 300 was formed without forming the mask layer 121. The nitride semiconductor layer 300 had a thickness of 3.3 μm.

### Results and Evaluation

### X-Ray Diffraction Profile

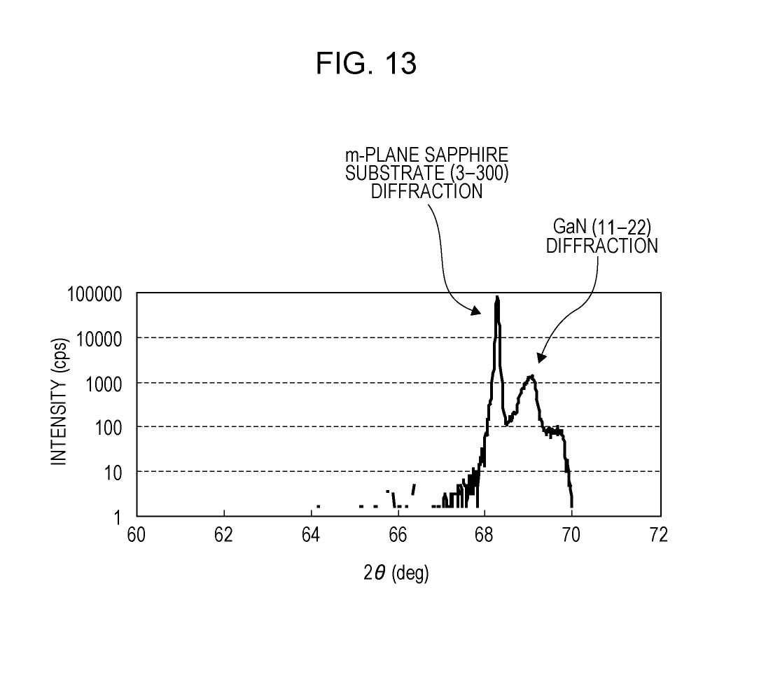

FIG. 13 is an X-ray diffraction profile of a nitride semiconductor multilayer structure of Comparative Example 1. As clear from FIG. 13, a diffraction peak of the (3-300) plane and a diffraction peak of the (11-22) plane were observed. The diffraction peak of the (3-300) plane was due to the diffraction from the principal surface of the m-sapphire substrate serving as the substrate 100. The diffraction peak of the (11-22) plane was due to the nitride semiconductor layer 300. No other diffraction peaks were observed. Thus, it was found that only a nitride semiconductor layer 300 having a (11-22) principal surface had been grown. In other words, the normal line of the principal surface of the nitride semiconductor layer 300 was parallel to the <11-22> crystal axis of the nitride semiconductor.

This means that a nitride semiconductor layer 300 having a (11-22) principal surface can be epitaxially grown on a surface of a substrate 100 by the method for growing a nitride semiconductor layer 300 according to this example.

### Scanning Electron Microscope (SEM) Image

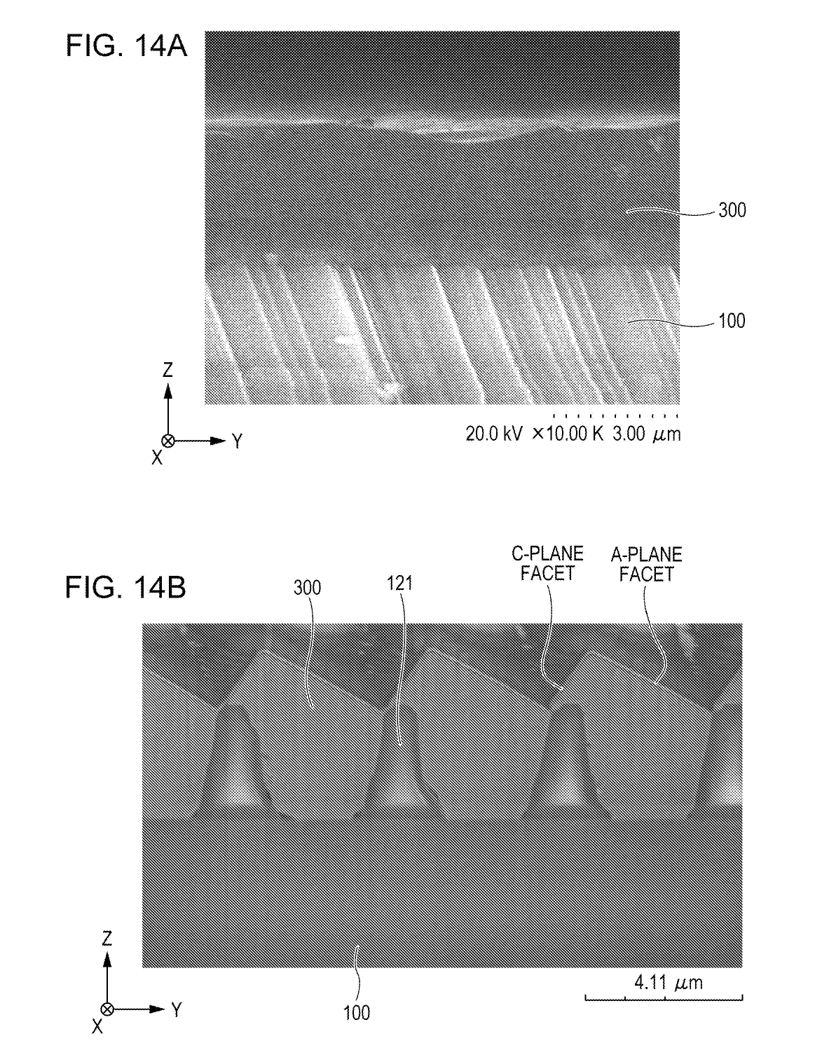

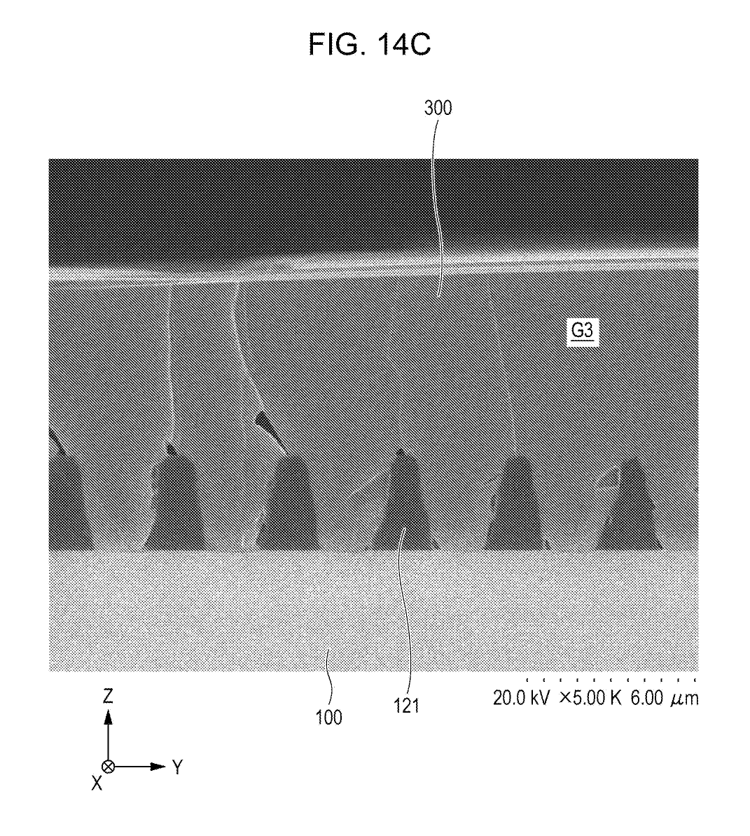

FIG. 14A is a scanning electron microscope image (SEM image) of a cross section of the nitride semiconductor multilayer structure according to Comparative Example 1. As understood from FIG. 14A, a uniform nitride semiconductor layer 300 having a (11-22) principal surface was formed on the substrate 100. The surface of the nitride semiconductor layer 300 was flat. However, the nitride semiconductor layer 300 according to Comparative Example 1 had a dislocation density as high as 10¹⁰ cm⁻² or more.

FIG. 14B is a cross-sectional SEM image of the nitride semiconductor multilayer structure according to Reference Example A. As understood from FIG. 14B, a nitride semiconductor layer 300 having a (11-22) principal surface was formed on the substrate 100. The surface of the nitride semiconductor layer 300 included A-plane facets and C-plane facets.

FIG. 14C is a cross-sectional SEM image of the nitride semiconductor multilayer structure according to Reference Example B. As understood from FIG. 14C, a uniform nitride semiconductor layer 300 having a (11-22) principal surface was formed on the substrate 100. The surface of the nitride semiconductor layer 300 was flat.

### Low-Temperature Photoluminescence Measurement

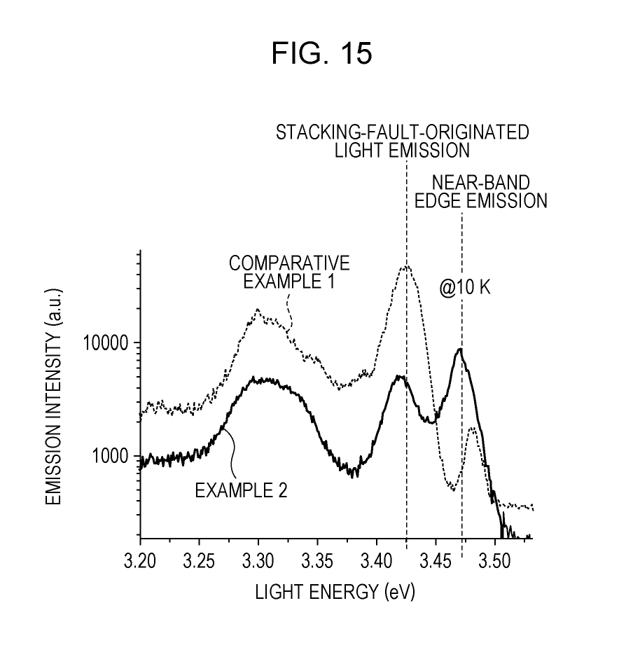

FIG. 15 indicates emission spectra of the nitride semiconductor layers 300 of Comparative Example 1 and Reference Example A at a low temperature of 10 K. The peak observed near 3.47 eV corresponds to the near-band edge emission (donor-bound exciton emission intensity). The peak observed near 3.42 eV corresponds to the emission attributable to stacking faults (hereinafter referred to as “stacking-fault-originated light emission”). The peak observed near 3.3 eV corresponds to emission due to other defects or dislocations.

As apparent from FIG. 15, the nitride semiconductor multilayer structure of Reference Example A had a higher near-band edge emission intensity than the nitride semiconductor multilayer structure of Comparative Example 1. The nitride semiconductor multilayer structure of Reference Example A had a smaller stacking-fault-originated light emission intensity than the nitride semiconductor multilayer structure of Comparative Example 1.

According to S. F. Chichibu et al., Optional properties of nearly stacking-fault-free m-plane GaN homoepitaxial films grown by metal organic vapor phase epitaxy on low defect density freestanding GaN substrates, Applied Physics Letters, vol. 92, page 091912 (2008), the peak due to near-band edge emission is observed near 3.47 eV (measured at 10 K).

As illustrated in FIG. 15, the peak due to donor-bound-exciton emission near the band edge of the nitride semiconductor multilayer structure of Reference Example A was observed near 3.471 eV. That of Comparative Example 1 was observed near 3.480 eV.

The difference between the peak (3.47 eV) of near-band edge emission according to S. F. Chichibu et al. and the peak (3.480 eV) of near-band edge emission according to Comparative Example 1 was about 0.01 eV, which is a relatively large value. This is because the nitride semiconductor layer 300 had residual strain.

The difference between the peak (3.47 eV) of near-band edge emission according to S. F. Chichibu et al. and the peak (3.471 eV) of near-band edge emission according to Reference Example A was about 0.001 eV, which is a small value. This is because the strain in the nitride semiconductor layer 300 had been relaxed. This means that, in the nitride semiconductor multilayer structure of Reference Example A, the densities of dislocations and stacking faults were decreased due to the selective growth technique used in this embodiment, resulting in positive alleviation of strain. This also means that the nitride semiconductor multilayer structure of Reference Example A has higher crystallinity than the nitride semiconductor multilayer structure of Comparative Example 1.

The ratio (about 1.79) of the donor-bound exciton emission intensity to the stacking-fault-originated emission intensity in Reference Example A is large compared to the ratio in Comparative Example 1, which is 0.04. This means that the density of stacking faults included in the nitride semiconductor multilayer structure of Example 1 is lower than the density of stacking faults included in the nitride semiconductor multilayer structure of Comparative Example 1.

### Transmission Electron Microscope (TEM) Image

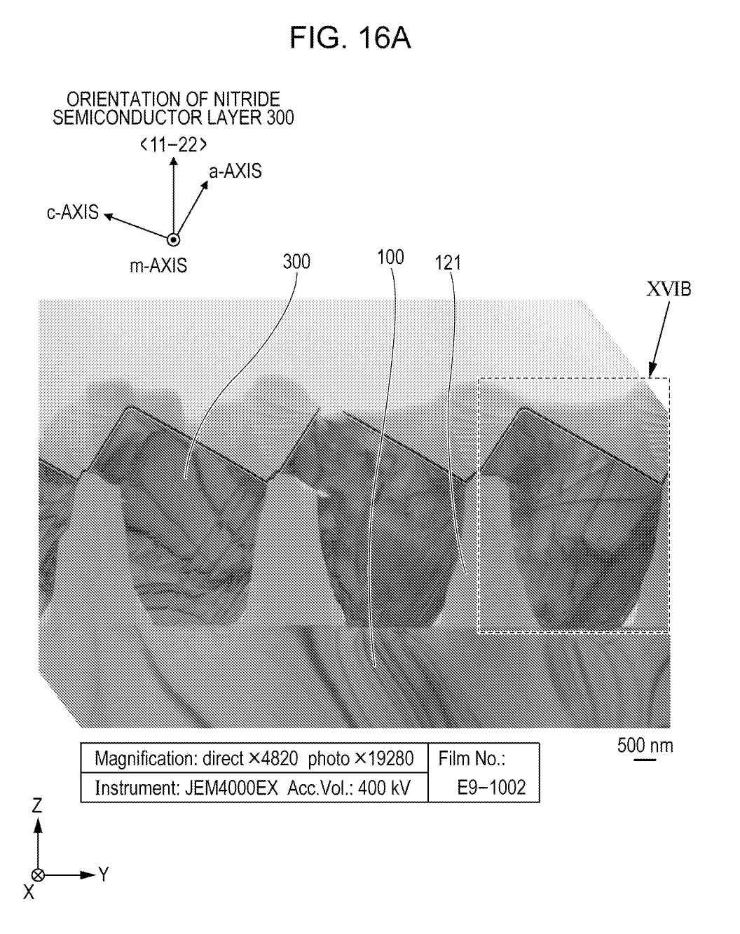

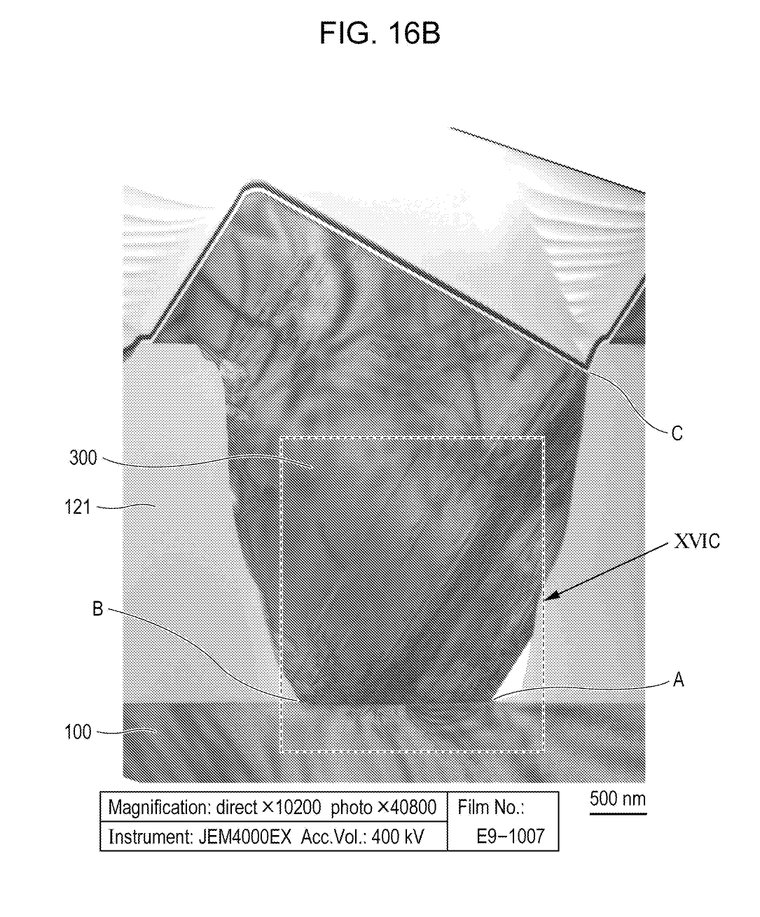

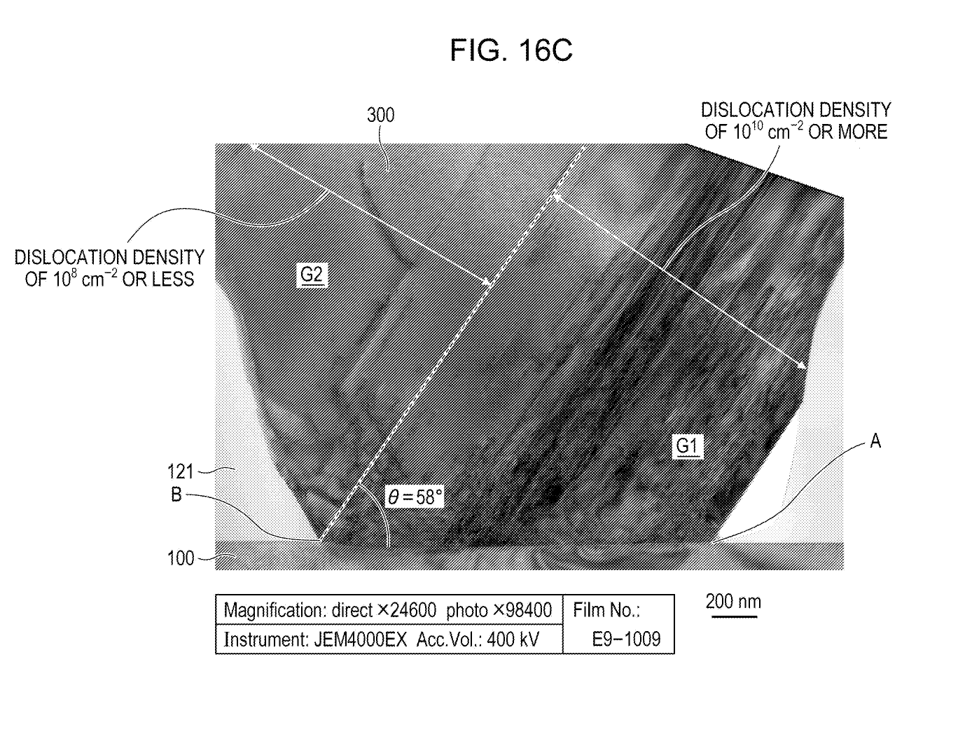

FIG. 16A is a cross-sectional transmission electron microscope image (hereinafter referred to as a “TEM image”) of the nitride semiconductor multilayer structure of Reference Example A. FIG. 16B is an enlarged view of a region surrounded by a broken line in FIG. 16A. FIG. 16C is an enlarged view of a region surrounded by a broken line in FIG. 16B.

The nitride semiconductor multilayer structure was sliced to a thickness of 100 nm in order to obtain a TEM image. The dislocation density was estimated from the thickness of the slice of the nitride semiconductor multilayer structure (100 nm), the widths of the regions G1, G2, and G3 (about 1 to 2 μm), and the number of dislocations.

As apparent from FIGS. 16A, 16B, and 16C, the nitride semiconductor layer in the first region G1 had many dislocations and many stacking faults. In contrast, the nitride semiconductor layer in the second region G2 had fewer dislocations and fewer stacking faults. These dislocations and stacking faults were formed in a direction orthogonal to the c-axis. In other words, the dislocations and stacking faults were formed to be parallel to the c plane.

To be more specific, the nitride semiconductor layer in the first region G1 had a dislocation density of 10¹⁰ cm⁻² or more. The nitride semiconductor layer in the second region G2 had a dislocation density of 10⁸ cm⁻² or less.

As illustrated in FIG. 14C, the third region G3 of Reference Example B was constituted by a nitride semiconductor layer epitaxially grown on the second region G2. The third region G3 of Reference Example A was also epitaxially grown on the second region G2. Thus, the nitride semiconductor layer was considered to have a dislocation density of 10⁸ cm⁻² or less.

Comparison Between Example 1 with Buffer Layer 110 and Reference Example A without Buffer Layer 110

As described above, according to the structures of Reference Examples A and B, a high-quality nitride semiconductor layer 300 having a low dislocation density was obtained by directly growing a nitride semiconductor layer 300 on a substrate 100 having a surface on which mask layer 121 was formed.

In other words, it is possible to reduce the dislocation density as in the embodiment by using the structure and method of Reference Examples A and B. However, it was found that Reference Examples A and B have a disadvantage that it is difficult to uniformly form a structure in the plane of the substrate 100.

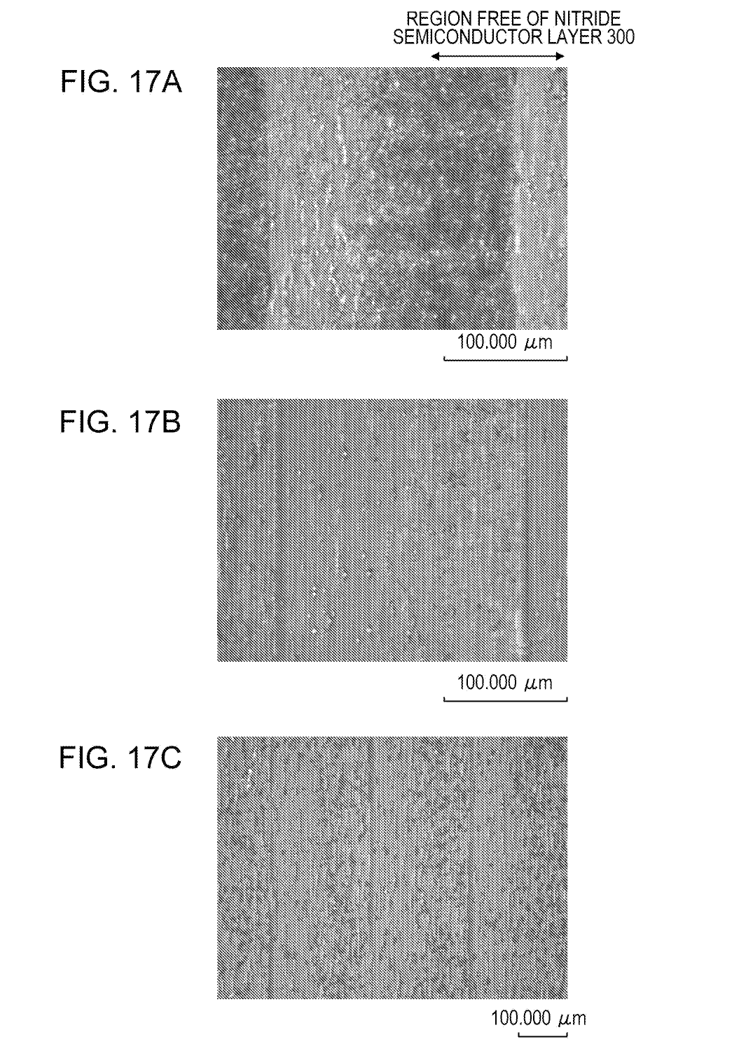

FIGS. 17A, 17B, and 17C are optical microscope images of a surface of Reference Example A. The magnification in FIGS. 17A, 17B, and 17C was the same (i.e. 50 times) and the images indicate the results of measurement taken at different positions in the sample plane.

The cross-sectional SEM image of FIG. 14B and cross-sectional TEM images of FIGS. 16A to 16C indicate the results of evaluation performed on a selected region having a relatively satisfactory surface morphology.

In other words, it has been clarified that, according to the structures and methods of Reference Examples A and B, although the structure same as that of the embodiment was observed in some parts, there were many other parts where the structure was not observed and the in-plane uniformity was particularly poor.

For example, there were parts in the region illustrated in FIG. 17A where the nitride semiconductor layer 300 was not formed at all.

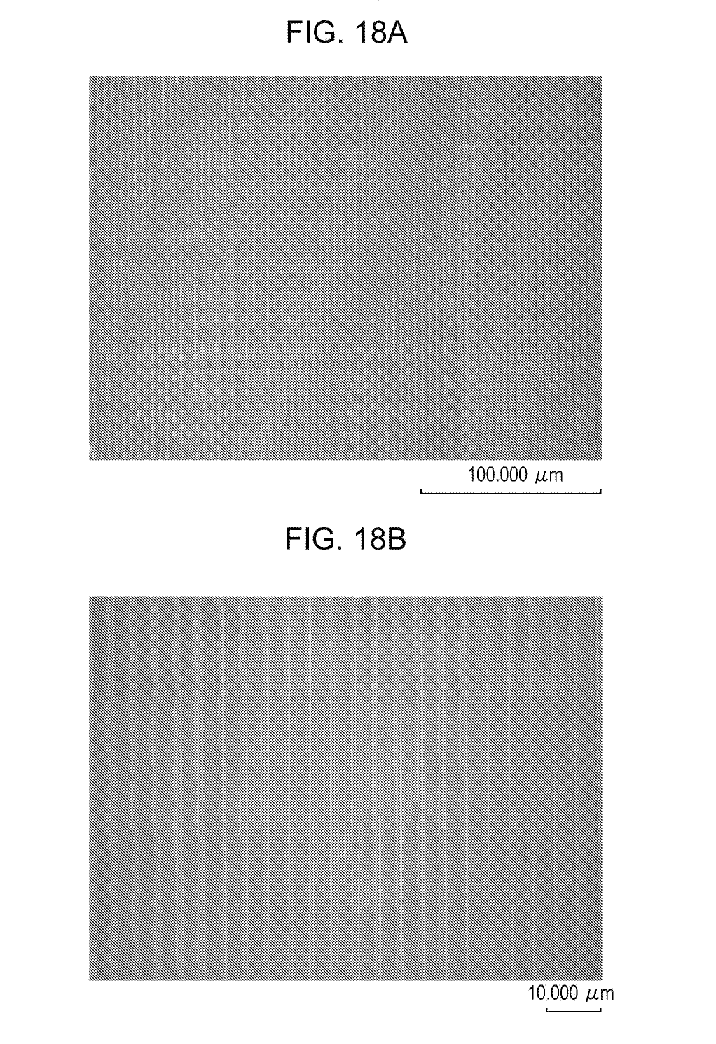

It has become clear that this problem of in-plane nonuniformity can be overcome by Example 1. FIGS. 18A and 18B are surface optical microscope images of Example 1.

Comparing FIGS. 18A and 18B to FIGS. 17A, 17B, and 17C makes it clear that the in-plane uniformity is significantly improved in Example 1. Regions where no nitride semiconductor layer 300 was grown were observed in some parts of Reference Examples A and B. In contrast, a satisfactory surface morphology was obtained in substantially all parts of the sample of Example 1 and it has been found that the structure of the embodiment is uniformly obtained in the sample plane.

### TEM Image of Example 1

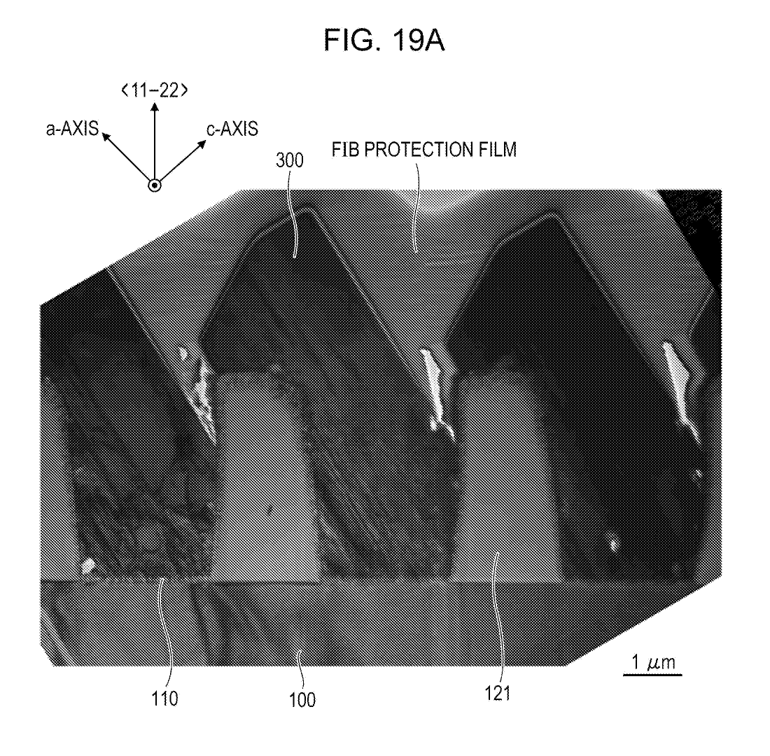

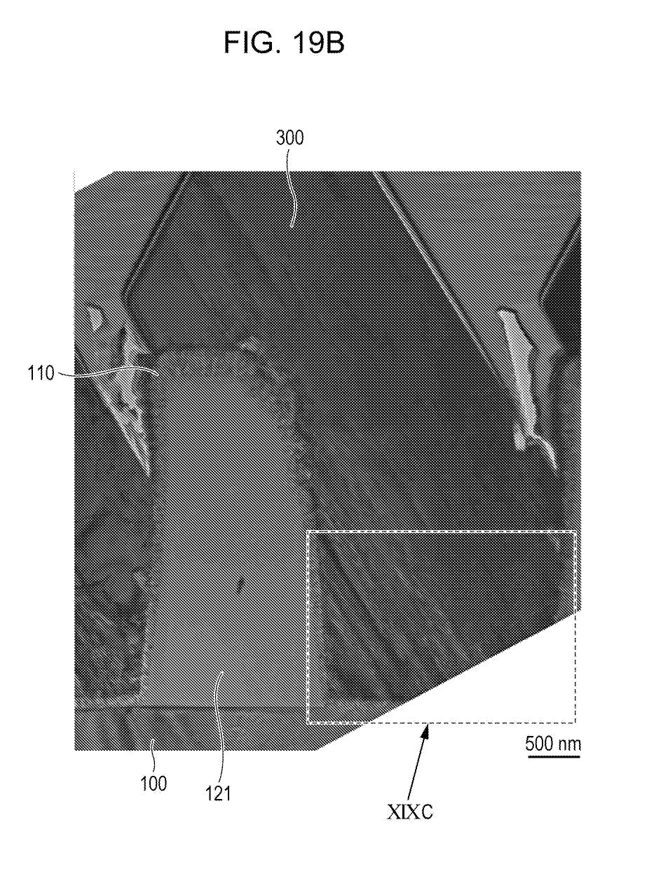

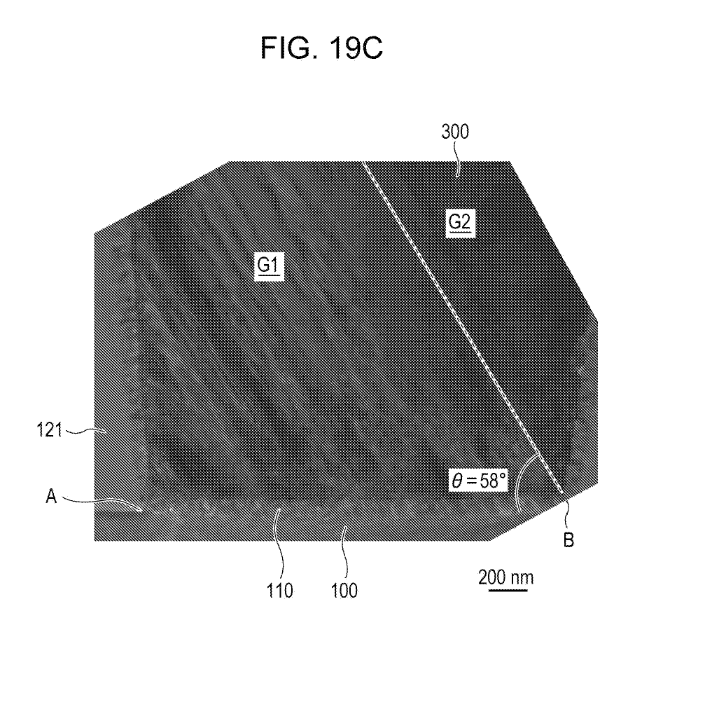

FIG. 19A is a cross-sectional TEM image of the nitride semiconductor multilayer structure of Example 1. FIG. 19B is an enlarged view of a central part of FIG. 19A. FIG. 19C is an enlarged view of a region surrounded by a broken line in FIG. 19B. FIGS. 19A, 19B, and 19C were evaluated by the same process as for the TEM images of Reference Example A in FIGS. 16A, 16B, and 16C. Note that the directions of the a-axis and the c-axis in FIGS. 19A, 19B, and 19C are opposite to those in FIGS. 16A, 16B, and 16C. This is because sides of the sample used for TEM measurement were flipped.

Comparing to Reference Example A in FIGS. 16A, 16B, and 16C, it is clear that Example 1 shown in FIGS. 19A, 19B, and 19C has a buffer layer 110 uniformly formed on a surface of the substrate 100 and the mask layer 121. This indicates that the buffer layer 110 formed on the substrate 100 is one of the factors that significantly improved the in-plane uniformity illustrated in FIGS. 17A to 17C.

As clear from FIGS. 19A, 19B, and 19C, the nitride semiconductor layer in the first region G1 has a high dislocation density and a high stacking fault density. In contrast, the dislocation density and stacking fault density are relatively low in the second region G2. The dislocations and stacking faults are formed in a direction orthogonal to the c-axis. In other words, the dislocations and stacking faults are formed to be parallel to the c plane.

In other words, it was confirmed that in the case of Example 1 where the buffer layer 110 was used, the same dislocation density reducing effect as that in Reference Example A was obtained and the in-plane uniformity was significantly improved.

It was found that, according to the structure of Example 1, the crystal structure of the buffer layer 110 in a portion formed on the surface of the substrate 100 is different from the crystal structure of the buffer layer 110 in a portion formed on the surface of each pattern of mask layer 121.

Dislocations and stacking faults in the buffer layer 110 formed on the surface of the substrate 100 are formed in a direction 58° tilted from the interface. Accordingly, it was found that the buffer layer 110 was a nitride semiconductor layer having a (11-22) principal surface as in Reference Example A.

In contrast, the structure of the buffer layer 110 formed on the surface of the mask layer 121 was a columnar polycrystal structure, as illustrated in FIG. 19B. This is because the SiO₂ film used as the mask layer 121 is amorphous-like and thus epitaxial growth of the buffer layer 110 rarely takes place on the surface of the mask layer 121.

Accordingly, in Example 1, the crystal structure of the buffer layer 110 formed on the surface of the substrate 100 is different from the crystal structure of the buffer layer 110 formed on the mask layer 121. It is presumed that, in Example 1, raw materials were deposited only onto the single crystal AlN buffer layer 110 having a (11-22) principal surface formed on the substrate 100, resulting in selective growth.

The reason behind the drastic improvement in the in-plane uniformity of the nitride semiconductor layer 300 in Example 1 compared to Reference Example A is probably the same. In other words, it is believed that, in the case where selective growth is conducted according to this embodiment, the surface of the buffer layer 110 on the region 100b, i.e., the surface of the single crystal nitride semiconductor having a (11-22) principal surface, promotes nucleation and selective growth compared to the surface of the substrate 100, the surface of the mask layer 121 composed of SiO₂, and the surface of a polycrystal-like nitride semiconductor formed on the mask layer 121.

Since the mask layer 121 used in the embodiment has a high aspect ratio, it has been anticipated that the raw materials may not reach the surface of the substrate 100 during growth. In Reference Example A, selective growth occurs from the surface of the substrate 100 as a starting point. Nucleation is difficult to occur on the surface of the substrate 100 compared to the surface of a nitride. Probably, this resulted in in-plane nonuniformity during formation of the nitride semiconductor layer 300 in Reference Example A as illustrated in FIG. 17A.

In Example 1, a low-temperature AlN layer is formed as the buffer layer 110. In other words, the starting point of the growth is not the surface of the sapphire substrate 100 but the surface of the nitride semiconductor (AlN surface) constituting the buffer layer 110. Probably it is due to this structure in Example 1 that deposited raw materials nucleate easily, selective growth is dramatically promoted, and in-plane uniformity is improved.

Thus, in this embodiment in which a mask having a high aspect ratio is used, the region that serves as the starting point of selective growth is made of a material that can induce selective growth. In particular, the region that serves as a starting point of selective growth is set to be the surface of the buffer layer 110 composed of a nitride semiconductor, not the surface of the sapphire substrate 100.

It is understood that a substrate having a nitride semiconductor layer on the surface can be used as the substrate 100 so that the surface of the nitride semiconductor layer can serve as the region from which the selective growth starts without using a buffer layer. However, if the method disclosed in S. F. Chichibu et al. is used, the process of growing crystals need to be performed twice as described above, resulting in a higher process cost.

Accordingly, as in Example 1, the dislocation density and the defect density can be significantly reduced by forming a mask layer 121 directly on the surface of a substrate 100, forming a buffer layer 110 at a low temperature, and then forming a nitride semiconductor layer 300 and this only requires performing the crystal growth process once.

### Reference Example 1

The same experiment as in Comparative Example 1 was performed except that an m-plane sapphire substrate having an off-angle of 5° relative to the c-axis was used as the substrate 100. The substrate 100 was available from Kyosera Corporation.

Since the substrate 100 had an off-angle of 5°, the angle θ in Reference Example 1 was 53° (=58°−5°).

### Reference Example 2

The same experiment as in Comparative Example 1 was performed except that a substrate 100 having an off-angle of 10° relative to the c-axis was used. The substrate 100 was available from Kyosera Corporation.

Since the substrate 100 had an off-angle of 10°, the angle θ in Reference Example 2 was 48° (=58°−10°).

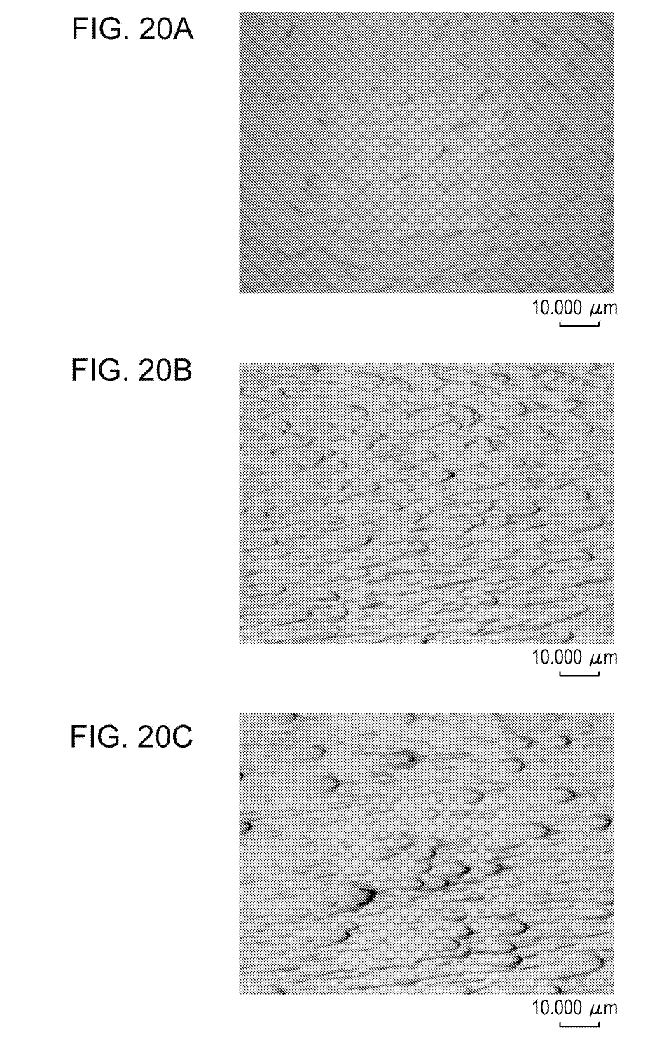

FIG. 20A illustrates a surface morphology of the nitride semiconductor multilayer structure according to Comparative Example 1. FIG. 20B illustrates a surface morphology of the nitride semiconductor multilayer structure according to Reference Example 1. FIG. 20C illustrates a surface morphology of the nitride semiconductor multilayer structure according to Reference Example 2. The surface morphology was observed with a laser microscope.

FIGS. 20A, 20B, and 20C indicate surface morphologies similar to one another. It can be understood from FIGS. 20A to 20C that a nitride semiconductor multilayer structure having a (11-22) principal surface is epitaxially grown when the angle θ is 48° or more and 58° or less.

Nitride semiconductor multilayer structures disclosed in this disclosure can be used in nitride semiconductor light-emitting devices and nitride semiconductor lasers.

While the present disclosure has been described with respect to preferred embodiments thereof, it will be apparent to those skilled in the art that the disclosure may be modified in numerous ways and may assume many embodiments other than those specifically described above. Accordingly, it is intended by the appended claims to cover all modifications of the disclosure that fall within the true spirit and scope of the disclosure.

What is claimed is:

1. A nitride semiconductor multilayer structure comprising:
a sapphire substrate having a principal surface which is an m-plane having an off-angle φ of 0° or more and 10° or less with respect to a c-axis;
a mask layer having a pattern that forms a plurality of exposed regions on the principal surface of the sapphire substrate, the mask layer comprising a first side surface portion and a second side surface portion sandwiching each of the exposed regions in a direction parallel to the c-axis of the sapphire substrate;
a buffer layer disposed on the plurality of exposed regions of the principal surface and the mask layer, the buffer layer comprising a nitride semiconductor; and
a nitride semiconductor layer disposed on the buffer layer,
wherein, in a cross section parallel to an m-axis and the c-axis of the sapphire substrate,
a point at which the first side surface portion of the mask layer meets the principal surface of the sapphire substrate is defined as point A,
a point at which the second side surface portion of the mask layer meets the principal surface of the sapphire substrate is defined as point B,
a point at which the first side surface portion intersects a straight line passing through point B and forming an angle 58°−φ with the principal surface is defined as point C,
a distance between a straight line passing through point C and perpendicular to the principal surface and a straight line passing through point B and perpendicular to the principal surface is defined as W,
a height of the first side surface portion is defined as H, and
H≧W·tan(58°−φ).

2. The nitride semiconductor multilayer structure according to claim 1, wherein, in the cross section parallel to the m-axis and the c-axis of the sapphire substrate,
a region defined by the principal surface, the first side surface portion, and a straight line connecting point B and point C is defined as a first region,
a region defined by the second side surface portion, the straight line connecting point B and point C, and a straight line passing through point C and parallel to the principal surface is defined as a second region,
a region above the straight line passing through point C and parallel to the principal surface is defined as a third region, and
the nitride semiconductor layer has a higher dislocation density in the first region than in the second region.

3. The nitride semiconductor multilayer structure according to claim 2, wherein the nitride semiconductor layer has the same dislocation density in the second region and the third region.

4. The nitride semiconductor multilayer structure according claim 3, wherein the nitride semiconductor layer has a dislocation density of 10⁸ cm⁻² or less in the third region.

5. The nitride semiconductor multilayer structure according to claim 4, wherein the nitride semiconductor layer has a dislocation density of 10¹⁰ cm⁻² or more in the first region.

6. The nitride semiconductor multilayer structure according to claim 2, wherein the nitride semiconductor layer has a dislocation density of 10⁸ cm⁻² or less in the second region.

7. The nitride semiconductor multilayer structure according to claim 1, wherein a crystal structure of the buffer layer on the plurality of exposed regions of the principal surface is different from a crystal structure of the buffer layer on the mask layer.

8. The nitride semiconductor multilayer structure according to claim 1, wherein the buffer layer on the plurality of exposed regions of the principal surface has the same plane orientation as that of the nitride semiconductor layer.

9. The nitride semiconductor multilayer structure according to claim 1, wherein the buffer layer comprises an aluminum-containing nitride semiconductor.

10. The nitride semiconductor multilayer structure according to claim 1, wherein the mask layer has a striped structure extending in an a-axis direction of the sapphire substrate and including a plurality of stripes that include a pair of stripes adjacent to each other, and
the first side surface portion and the second side surface portion are side surfaces of the pair of stripes, the side surfaces opposing each other.

11. The nitride semiconductor multilayer structure according to claim 1, wherein the mask layer includes a plurality of independent openings, and
the plurality of exposed regions of the principal surface are located at bottoms of the plurality of openings.

12. The nitride semiconductor multilayer structure according to claim 11, wherein each of the plurality of openings has a round shape.

13. The nitride semiconductor multilayer structure according to claim 11, wherein each of the plurality of openings has a stripe shape.

14. An electronic device comprising the nitride semiconductor multilayer structure according to claim 1.

15. A nitride semiconductor bulk substrate comprising the nitride semiconductor multilayer structure according to claim 1.

16. A light-emitting device comprising:
the nitride semiconductor multilayer structure according to claim 1;
an additional nitride semiconductor multilayer structure disposed on the nitride semiconductor multilayer structure, the additional nitride semiconductor multilayer structure including an n-type nitride semiconductor layer, a p-type nitride semiconductor layer, and an active layer sandwiched between the n-type nitride semiconductor layer and the p-type nitride semiconductor layer;
an n-side electrode in contact with and electrically connected to the n-type nitride semiconductor layer; and
a p-side electrode in contact with and electrically connected to the p-type nitride semiconductor layer.

17. A method for manufacturing a nitride semiconductor multilayer structure, the method comprising:
preparing a sapphire substrate having a principal surface which is an m-plane having an off-angle φ of 0° or more and 10° or less with respect to a c-axis;
forming a mask layer on the principal surface of the sapphire substrate, the mask layer having a pattern that forms a plurality of exposed regions on the principal surface of the sapphire substrate, the mask layer comprising a first side surface portion and a second side surface portion sandwiching each of the exposed regions in a direction parallel to the c-axis of the sapphire substrate; forming a buffer layer on the plurality of exposed regions of the principal surface and the mask layer by using a nitride semiconductor; and
epitaxially growing a nitride semiconductor layer on the buffer layer,
wherein, in a cross section parallel to an m-axis and the c-axis of the sapphire substrate,
a point at which the first side surface portion of the mask layer meets the principal surface of the sapphire substrate is defined as point A,
a point at which the second side surface portion of the mask layer meets the principal surface of the sapphire substrate is defined as point B,
a point at which the first side surface portion intersects a straight line passing through point B and forming an angle 58°−φ with the principal surface is defined as point C,
a distance between a straight line passing through point C and perpendicular to the principal surface and a straight line passing through point B and perpendicular to the principal surface is defined as W,
a height of the first side surface portion is defined as H, and
H≧W·tan(58°−φ).
